(19) United States
(12) Patent Application Publication
(10) Pub. No.: US 2025/0056797 A1
(43) Pub. Date: Feb. 13, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: In Ku KANG, Gyeonggi-do (KR)

(21) Appl. No.: 18/529,320

(22) Filed: Dec. 5, 2023

(30) Foreign Application Priority Data
Aug. 11, 2023 (KR) 10-2023-0105301

(51) Int. Cl. H10B 43/27; H10B 41/27

(52) U.S. Cl. CPC H10B 43/27; H10B 41/27

(57) ABSTRACT

A semiconductor device may include a first support including a first inclined surface, a first gate structure including first insulating layers and first conductive layers alternately stacked along the first inclined surface, a second support positioned over or on the first support and including a second inclined surface, a second gate structure including second insulating layers and second conductive layers alternately stacked along the second inclined surface, a first contact plug extending through the second gate structure and connected to at least one first conductive layer among the first conductive layers, and a second contact plug disposed over or on the second gate structure and connected to at least one second conductive layer among the second conductive layers.

### CROSS-REFERENCE TO RELATED APPLICATION

This application claims priority under 35 U.S.C. § 119 to Korean Patent Application No. 10-2023-0105301 filed on Aug. 11, 2023, which is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by the area occupied by a unit memory cell. Recently, as improvements in the integration degree of a semiconductor device in which a memory cell is formed as a single layer on a substrate reach a limit, three-dimensional semiconductor devices in which memory cells are stacked on a substrate have been proposed. In addition, various structures and manufacturing methods are being developed to improve operation reliability of the three-dimensional semiconductor devices.

### SUMMARY

According to an embodiment of the present disclosure, a semiconductor device may include a first support including a first inclined surface, a first gate structure including first insulating layers and first conductive layers alternately stacked along the first inclined surface, a second support positioned over or on the first support and including a second inclined surface, a second gate structure including second insulating layers and second conductive layers alternately stacked along the second inclined surface, a first contact plug extending through the second gate structure and connected to at least one first conductive layer among the first conductive layers, and a second contact plug disposed over or on the second gate structure and connected to at least one second conductive layer among the second conductive layers.

According to an embodiment of the present disclosure, a semiconductor device may include a first support including a first inclined surface, a first gate structure including first insulating layers and first conductive layers alternately stacked along the first inclined surface, a second support positioned over or on the first support and including a second inclined surface, a second gate structure including second insulating layers and second conductive layers alternately stacked along the second inclined surface, a channel structure extending through the second gate structure and the first gate structure, a first contact plug including a top surface positioned at substantially the same level as a top surface of the channel structure, on the first gate structure, and a second contact plug connected to at least one second conductive layer among the second conductive layers, on the second gate structure.

According to an embodiment of the present disclosure, a method of manufacturing a semiconductor device may include forming a first support including a first inclined surface, forming a first stack including first material layers and second material layers alternately stacked along the first inclined surface, forming a second support including a second inclined surface on the first support, forming a second stack including third material layers and fourth material layers alternately stacked along the second inclined surface, forming a first contact opening extending through the second stack and exposing at least one second material layer among the second material layers, and forming a first contact plug in the first contact opening.

According to an embodiment of the present disclosure, a method of manufacturing a semiconductor device may include forming a first support including a first inclined surface, forming a first stack including first material layers and second material layers alternately stacked along the first inclined surface, forming a first channel sacrificial layer in the first stack, forming a second support including a second inclined surface on the first support, forming a second stack including third material layers and fourth material layers alternately stacked along the second inclined surface, forming a channel opening exposing the first channel sacrificial layer in the second stack, forming a first contact opening exposing at least one second material layer among the second material layers when forming the channel opening, forming a second contact opening exposing at least one fourth material layer among the fourth material layers, forming a first contact plug in the first contact opening, and forming a second contact plug in the second contact opening.

These and other features and advantages of the embodiments of the present disclosure will become apparent to those with ordinary skill in the art from the following drawings and detailed description.

### BRIEF DESCRIPTION OF THE DRAWINGS

FIGS. 1A to 1D are diagrams illustrating a semiconductor device according to an embodiment of the present disclosure.

FIGS. 2A to 2D are diagrams illustrating a semiconductor device according to an embodiment of the present disclosure.

FIGS. 3A to 10B are diagrams illustrating a method of manufacturing a semiconductor device according to an embodiment of the present disclosure.

FIGS. 11A to 17B are diagrams illustrating a method of manufacturing a semiconductor device according to an embodiment of the present disclosure.

FIGS. 18A to 22B are diagrams illustrating a method of manufacturing a semiconductor device according to an embodiment of the present disclosure.

FIGS. 23A to 28B are diagrams illustrating a method of manufacturing a semiconductor device according to an embodiment of the present disclosure.

FIGS. 29A to 33B are diagrams illustrating a method of manufacturing a semiconductor device according to an embodiment of the present disclosure.

FIGS. 34A to 36B are diagrams illustrating a method of manufacturing a semiconductor device according to an embodiment of the present disclosure.

### DETAILED DESCRIPTION

According to an aspect of the present disclosure a semiconductor device is provided having a stable structure and improved characteristic. According to another aspect of the present disclosure a method of manufacturing the semiconductor device is also provided.

Hereinafter, various embodiments according to the technical concepts of the present disclosure are described with reference to the accompanying drawings.

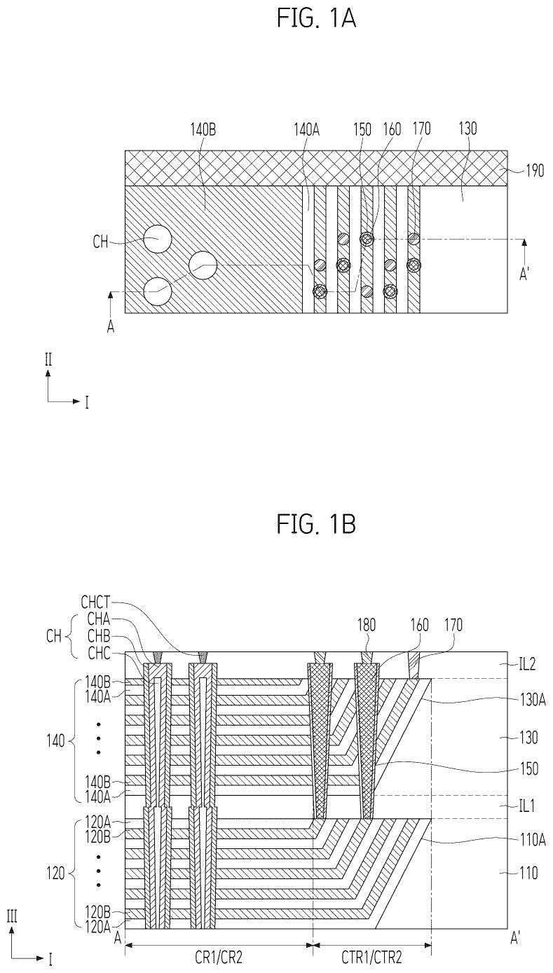

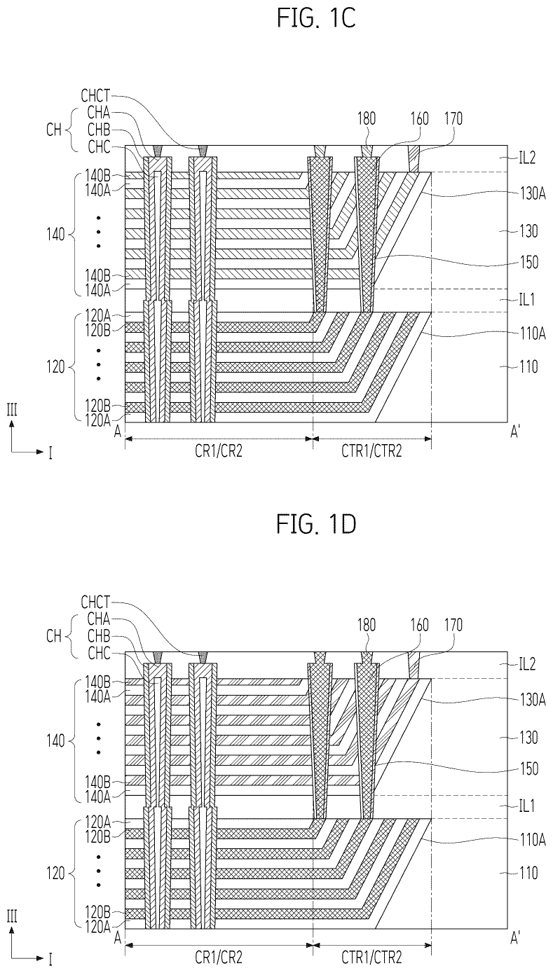

FIGS. 1A to 1D are diagrams illustrating a semiconductor device according to an embodiment of the present disclosure. FIG. 1A is a plan view, and FIGS. 1B, 1C, and 1D are cross-sectional views along line A-A′ of FIG. 1A.

Referring now to FIGS. 1A to 1D, the semiconductor device may include a first support 110, a first gate structure 120, a second support 130, a second gate structure 140, a first contact plug 160, a second contact plug 170, a third contact plug 180, and a slit structure 190. The semiconductor device may further include an insulating spacer 150, a channel contact plug CHCT, a first interlayer insulating layer IL1, a second interlayer insulating layer IL2, or a channel structure CH, or may further include a combination thereof.

The first support 110 may include a first inclined surface 110A. The first inclined surface 110A may have an inclination of an acute angle. Acute angle means an angle of over 0 degrees to less than 90 degrees or stated differently between 0 and 90 degrees. For example, the acute angle may be about 60 degrees. The first support 110 may include an insulating material such as an oxide.

The second support 130 may be positioned over or on the first support 110. The second support 130 may include a second inclined surface 130A. For example, the second inclined surface 130A may have an inclination of an acute angle. The second inclined surface 130A may have an inclination substantially equal to, or equal to, or different from that of the first inclined surface 110A.

The first gate structure 120 may be positioned over or on the first support 110 and may include first insulating layers 120A and first conductive layers 120B alternately stacked. For example, the first gate structure 120 may include the first insulating layers 120A and the first conductive layers 120B alternately stacked along the first inclined surface 110A. The first gate structure 120 may include a first cell region CR1 in which the first conductive layers 120B extend in a first direction I and a first contact region CTR1 extending along the first inclined surface 110A. In the first contact region CTR1, a top surface of each of the first conductive layers 120B may be positioned at substantially the same level.

The second gate structure 140 may be positioned over or on the second support 130 and may include second insulating layers 140A and second conductive layers 140B alternately stacked. For example, the second gate structure 140 may include the second insulating layers 140A and the second conductive layers 140B alternately stacked along the second inclined surface 130A. The second gate structure 140 may include a first cell region CR1 in which the second conductive layers 140B extend in the first direction I and a second contact region CTR2 extending along the second inclined surface 130A. In the second contact region CTR2, a top surface of each of the second conductive layers 140B may be positioned at substantially the same level.

The first and second gate structures 120 and 140 may overlap with each other. For example, in a third direction III crossing the first direction I, the first and second cell regions CR1 and CR2 may overlap with each other. In addition, in the third direction III, the first and second contact regions CTR1 and CTR2 may overlap with each other. For example, the first direction I may be a horizontal direction in which the first conductive layers 120B extend, and the third direction III may be a vertical direction in which the first conductive layers 120B are stacked. However, the present disclosure is not limited thereto, and the first cell region CR1 and the second contact region CTR2 may partially overlap, and the second cell region CR2 and the first contact region CTR1 may not overlap with each other. By overlapping the first and second cell regions CR1 and CR2 and overlapping the first and second contact regions CTR1 and CTR2, the area occupied by the first and second gate structures 120 and 140 in the semiconductor device is reduced. Therefore, the integration degree of the semiconductor device may be improved significantly. Integration degree as this term is used here means how tightly the various elements of the semiconductor device are packed or integrated into the semiconductor wafer or chip and may also be referred to as semiconductor device density or compactness. This is an important improvement because increasing semiconductor device integration can lead to more powerful and efficient electronic devices.

The channel structure CH may extend through the second and first gate structures 140 and 120. The channel structure CH may be positioned in the second cell region CR2 of the second gate structure 140 and the first cell region CR1 of the first gate structure 120. The channel structure CH may include a channel layer CHA. The channel structure CH may further include a memory layer CHB surrounding the channel layer CHA and an insulating core CHC formed inside the channel layer CHA. The channel structure CH may include a channel layer CHA. The channel layer CHA and the memory layer CHB may extend along the III direction from the bottom to the top of the channel structure CH. The insulating core CHC may extend along the III direction from the bottom of the channel structure CH to a level that is lower than the top of the channel structure CH. A top surface of the insulating core CHC may be covered by the channel layer CHA.

The slit structure 190 may extend through the second and first gate structures 140 and 120. The slit structure 190 may extend in the first direction I. The slit structure 190 may be an insulating layer formed in a slit (not shown) used as a path for replacing sacrificial layers (not shown) with the first conductive layers 120B and the second conductive layers 140B during a manufacturing process. Alternatively, the slit structure 190 may include a source contact structure connected to a source structure.

The first contact plug 160 may extend through the second gate structure 140 and may be connected to at least one first conductive layer 120B among the first conductive layers 120B. Each of the first contact plugs 160 may be connected to at least one first conductive layer 120B among the first conductive layers 120B. The height of the first contact plugs 160 may be substantially the same. A top surface of the first contact plug 160 may be positioned at substantially the same level as a top surface of the channel structure CH.

The first contact plug 160 may be positioned in the first and second contact regions CTR1 and CTR2. The first contact plug 160 may extend through the first interlayer insulating layer IL1 and may be connected to at least one of the first conductive layers 120B. The first interlayer insulating layer IL1 may be positioned between the first and second gate structures 120 and 140. The first contact plug 160 may include a conductive material such as tungsten. The first interlayer insulating layer IL1 may include an insulating material such as an oxide.

In some embodiments, the first contact plug 160 may be connected to at least one first conductive layer 120B among the first conductive layers 120B and may form a single layer. However, the present disclosure is not limited thereto, and the first contact plug 160 and the first conductive layer 120B may be layers formed through separate processes. Referring now to FIG. 1B, the first contact plug 160 and the first conductive layer 120B may be layers formed through separate processes. An interface may exist between the first contact plug 160 and the first conductive layer 120B. However, according to the material(s) used, the various parameters of the deposition method(s) employed for the formation of the first contact plug 160 and the first conductive layer 120B and the interface between them not be readily identifiable or not identifiable at all. Referring now to FIGS. 1C and 1D, the first contact plug 160 and the first conductive layer 120B may be connected and may form a single layer.

The insulating spacer 150 may cover a sidewall of the first contact plug 160. The insulating spacer 150 may electrically isolate the first contact plug 160 and the second gate structure 140. Because the first contact plug 160 extends through the second gate structure 140 and is connected to at least one first conductive layer 120B among the first conductive layers 120B of the first gate structure 120, the first contact plug 160 is required to be electrically isolated from the second conductive layers 140B. Therefore, the insulating spacer 150 may be positioned between the first contact plug 160 and the second gate structure 140 to electrically isolate (or insulate) the first contact plug 160 and the second gate structure 140. The insulating spacer 150 may include an insulating material such as an oxide.

The second contact plug 170 may be positioned over or on the second gate structure 120 and may be connected to at least one second conductive layer 140B among the second conductive layers 140B. Each of the second contact plugs 170 may be connected to at least one second conductive layer 140B among the second conductive layers 140B. A height of the second contact plugs 170 may be substantially the same.

The second contact plug 170 may be positioned in the first and second contact regions CTR1 and CTR2. The second contact plug 170 may be adjacent to the first contact plug 160 in a second direction II crossing the first direction I and the third direction III. This is because the first contact plug 160 and the second contact plug 170 are positioned in an overlapping region of the first and second gate structures 120 and 140. For example, the second direction II may mean a horizontal direction crossing the first direction I on the same plane as the first direction I. The second contact plug 170 may extend through the second interlayer insulating layer IL2 and may be connected to at least one of the second conductive layers 140B. For example, the second interlayer insulating layer IL2 may be positioned over or on the second gate structure 140. The second contact plug 170 may include a conductive material such as tungsten. The second interlayer insulating layer IL2 may include an insulating material such as an oxide.

The second contact plug 170 may be connected to at least one second conductive layer 140B among the second conductive layers 140B and may form a single layer. However, the present disclosure is not limited thereto, and the second contact plug 170 and the second conductive layer 140B may be layers formed through separate processes. Referring now to FIGS. 1B and 1C, the second contact plug 170 and the second conductive layer 140B may be layers formed through separate processes. An interface may exist between the second contact plug 170 and the second conductive layer 140B. However, according to the material(s) and deposition method(s) employed for forming the second contact plug 170 and the second conductive layer 140B their interface may not be readily identifiable or not identifiable at all. Referring now to FIG. 1D, the second contact plug 170 and the second conductive layer 140B may be connected and may form a single layer.

The third contact plug 180 may be positioned over or on the first contact plug 160 and may be connected to the first contact plug 160. Each of the third contact plugs 180 may be connected to at least one first contact plug 160 among the first contact plugs 160. A height of the third contact plugs 180 may be substantially the same. A top surface of the third contact plug 180 may be positioned at substantially the same level as a top surface of the second contact plug 170. The third contact plug 180 may be positioned in the first and second contact regions CTR1 and CTR2. The third contact plug 180 may be adjacent to the second contact plug 170 in the second direction II. The third contact plug 180 may extend through the second interlayer insulating layer IL2 and may be connected to the first contact plug 160.

The third contact plug 180 may be connected to at least one first conductive layer 120B among the first conductive layers 120B and the first contact plug 160 and may form a single layer. However, the present disclosure is not limited thereto, and the third contact plug 180, the first conductive layer 120B, and the first contact plug 160 may be layers formed through separate processes. Referring now to FIGS. 1B and 1C, the third contact plug 180, the first conductive layer 120B, and the first contact plug 160 may be layers formed through separate processes. However, according to the material(s) and the deposition method(s) employed for making the third contact plug 180, the first conductive layer 120B, and the first contact plug 160 the interface may not be readily identifiable, or identifiable at all. Referring now to FIG. 1D, the third contact plug 180, the first conductive layer 120B, and the first contact plug 160 may be connected and may form a single layer.

The channel contact plug CHCT may be positioned over or on the channel structure CH. The channel contact plug CHCT may extend through the second interlayer insulating layer IL2 and may be connected to the channel structure CH. A top surface of the channel contact plug CHCT may be positioned at substantially the same level as a top surface of the second contact plug 170 and a top surface of the third contact plug 180. The channel contact plug CHCT may include a conductive material such as tungsten.

According to the structure as described above, the first and second gate structures 120 and 140 may overlap with each other. Therefore, an area occupied by the first and second gate structures 120 and 140 in the semiconductor device may be reduced, and an integration degree of the semiconductor device may be improved.

The first contact plug 160 connected to at least one first conductive layer 120B among the first conductive layers 120B of the first gate structure 120 may extend through the second gate structure 140. For example, to prevent electrical connection between the second conductive layers 140B of the second gate structure 140 and the first contact plug 160, the insulating spacer 150 may be formed to surround the sidewall of the first contact plug 160.

The first contact plug 160 and the first conductive layer 120B may be connected and may form a single layer. Alternatively, the first contact plug 160, the first conductive layer 120B, and the third contact plug 180 may be connected and may form a single layer. Alternatively, the second contact plug 170 and the second conductive layer 140B may be connected and may form a single layer. The process time, cost and complexity may be reduced significantly by forming in a single operation the first contact plug 160, the second contact plug 170, the third contact plug 180, the first conductive layer 120B, or the second conductive layer 140B.

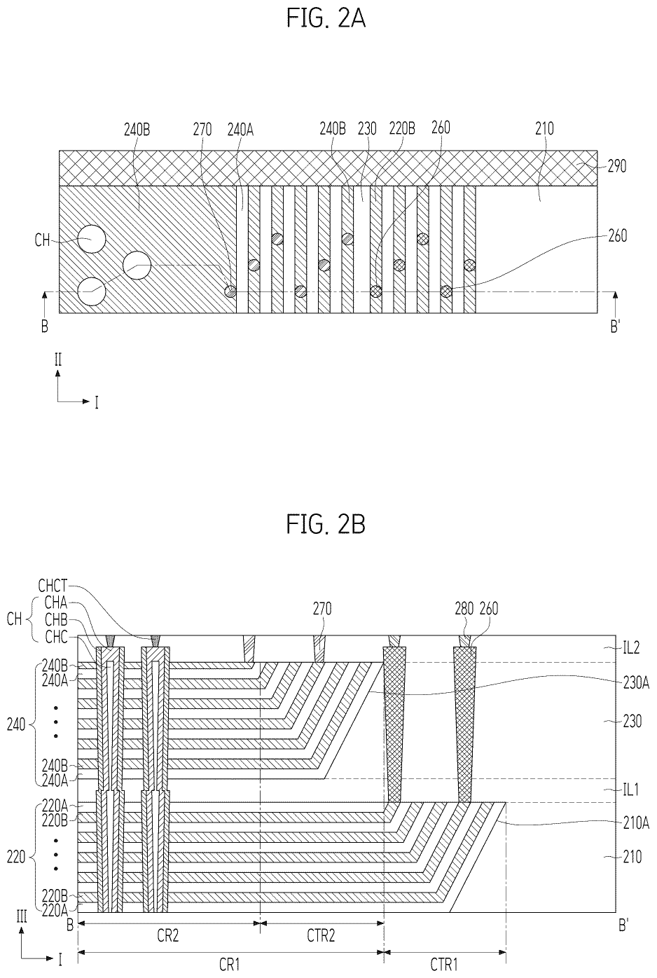

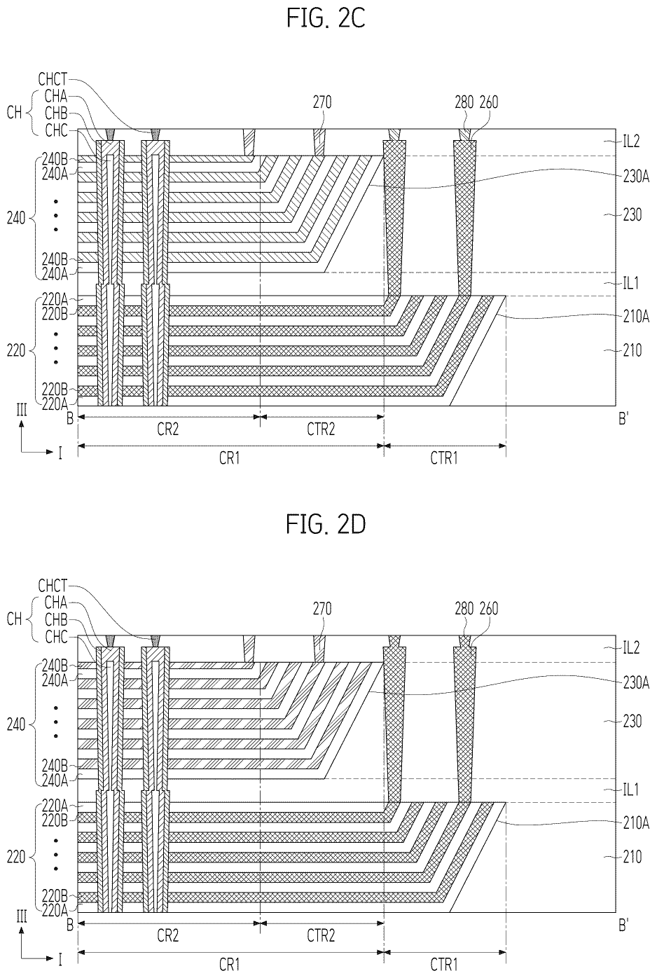

FIGS. 2A to 2D are diagrams illustrating a semiconductor device according to an embodiment of the present disclosure. FIG. 2A is a plan view, and FIGS. 2B to 2D are B-B′ cross-sectional views of FIG. 2A. Hereinafter, any content repetitive to previously described content may be omitted.

Referring now to FIGS. 2A to 2D, the semiconductor device may include a first support 210, a first gate structure 220, a second support 230, a second gate structure 240, a first contact plug 260, a second contact plug 270, a third contact plug 280, or a slit structure 290, or may include a combination thereof. The semiconductor device may further include the channel contact plug CHCT, the first interlayer insulating layer IL1, the second interlayer insulating layer IL2, or the channel structure CH, or may further include a combination thereof.

The first support 210 may include a first inclined surface 210A, and the second support 230 may include a second inclined surface 230A. For example, the second support 230 may be positioned over or on the first support 210. The first inclined surface 210A and the second inclined surface 230A may have an inclination of an acute angle. Acute angle means an angle between 0 and 90 degrees. For example, the acute angle may be about 60 degrees. The first support 210 and the second support 230 may include an insulating material such as an oxide.

The first gate structure 220 may be positioned over or on the first support 210 and may include first insulating layers 220A and first conductive layers 220B alternately stacked along the first inclined surface 210A. The first gate structure 220 may include a first cell region CR1 in which the first conductive layers 220B extend in the first direction I and a first contact region CTR1 extending along the first inclined surface 210A. In the first contact region CTR1, a top surface of the first conductive layers 220B may be positioned at substantially the same level.

The second gate structure 240 may be positioned over or on the second support 230 and may include second insulating layers 240A and second conductive layers 240B alternately stacked along the second inclined surface 230A. The second gate structure 240 may include the second cell region CR2 in which the second conductive layers 240B extend in the first direction I and a second contact region CTR2 extending along the second inclined surface 230A. In the second contact region CTR2, a top surface of the second conductive layers 240B may be positioned at substantially the same level.

The first gate structure 220 and the second gate structure 240 may overlap with each other. For example, in the third direction III crossing the first direction I, the first cell region CR1 may overlap with second cell region CR2 and the second contact region CTR2. The first contact region CTR1 may not overlap with second cell region CR2 and the second contact region CTR2. For example, the first direction I may be a horizontal direction in which the first conductive layers 220B extend, and the third direction III may be a vertical direction in which the first conductive layers 220B are stacked. However, the present disclosure is not limited thereto, and the first and second contact regions CTR1 and CTR2 may not overlap with each other.

The first contact plug 260 may extend through the second support 230 and may be connected to at least one first conductive layer 220B among the first conductive layers 220B. A height of the first contact plugs 260 may be substantially the same. Aa top surface of the first contact plug 260 may be positioned at substantially the same level as a top surface of the channel structure CH. The first contact plug 260 may be positioned in the first contact region CTR1. Because the first contact plug 260 extends through the second support 230, a separate insulating spacer is not required. The first contact plug 260 may include a conductive material such as tungsten.

The second contact plug 270 may be connected to at least one second conductive layer 240B among the second conductive layers 240B. A height of the second contact plugs 270 may be substantially the same. The second contact plug 270 may be positioned in the second contact region CTR2. The second contact plug 270 may be spaced apart from the first contact plug 260 in the first direction I. For example, the second contact plug 270 may be positioned in the second contact region CTR2, and the first contact plug 260 may be positioned in the first contact region CTR1 spaced apart from the second contact region CTR2. The second contact plug 270 may include a conductive material such as tungsten.

The third contact plug 280 may be positioned over or on the first contact plug 260 and may be connected to the first contact plug 260. A height of the third contact plugs 280 may be substantially the same. A top surface of the third contact plug 280 may be positioned at substantially the same level as a top surface of the second contact plug 270. The third contact plug 280 may be spaced apart from the second contact plug 270 in the first direction I. The third contact plug 280 may include a conductive material such as tungsten.

The first conductive layer 220B, the first contact plug 260, and the third contact plug 280 may be connected and may form a single layer or may not be connected as a single layer. In addition, the second conductive layer 240B and the second contact plug 270 may be connected and may form a single layer or may not be connected as a single layer. Referring now to FIG. 2B, the first conductive layer 220B, the first contact plug 260, and the third contact plug 280 may be layers formed through separate processes. The second conductive layer 240B and the second contact plug 270 may be formed through separate processes. Referring to FIG. 2C, the first conductive layer 220B and the first contact plug 260 may be connected and may form a single layer. The third contact plug 280 may be a layer formed through a process separated from that of the first conductive layer 220B and the first contact plug 260. The second conductive layer 240B and the second contact plug 270 may be layers formed through separate processes. Referring to FIG. 2D, the first conductive layer 220B, the first contact plug 260, and the third contact plug 280 may be connected and may form a single layer. The second conductive layer 240B and the second contact plug 270 may be connected and may form a single layer. However, in a case of FIGS. 2B to 2D, an interface may not be readily identifiable or identifiable at all according to the material(s) and the deposition method(s) employed for making the first conductive layer 220B, the second conductive layer 240B, the first contact plug 260, the second contact plug 270, and the third contact plug 280.

According to the structure described above, the first contact region CTR1 of the first gate structure 220 and the second contact region CTR2 of the second gate structure 240 may not overlap with each other. Therefore, the first contact plugs 260 and the third contact plugs 280 may be positioned in the first contact region CTR1, and the second contact plugs 270 may be positioned in the second contact region CTR2 spaced apart from the first contact region CTR1 in the first direction I.

The first contact plug 260, the first conductive layer 220B, and the third contact plug 280 may be connected and may form a single layer. Alternatively, the second contact plug 270 and the second conductive layer 240B may be connected and may form a single layer. The process time, cost and complexity may be reduced significantly by forming in a single operation the first conductive layer 220B, the first contact plug 260, or the third contact plug 280 or a process of forming the second conductive layer 240B or the second contact plug 270.

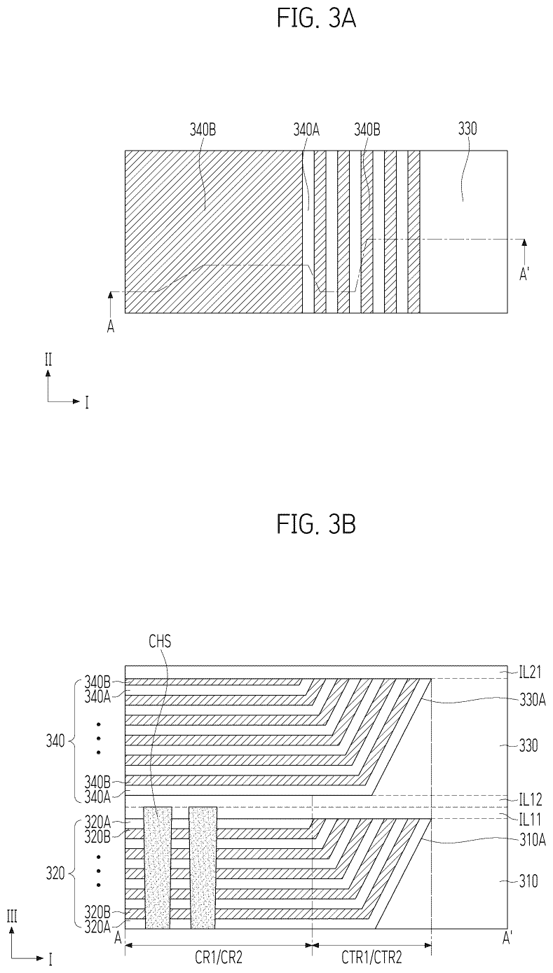

FIGS. 3A to 10B are diagrams illustrating a method of manufacturing a semiconductor device according to an embodiment of the present disclosure. FIGS. 3A, 4A, 5A, 6A, 7A, 8A, 9A, and 10A are plan views, and FIGS. 3B, 4B, 5B, 6B, 7B, 8B, 9B, and 10B are A-A′ cross-sectional views of each A view. Hereinafter, any content repetitive to previously described content may be omitted.

Referring now to FIGS. 3A and 3B, a first support 310 including a first inclined surface 310A may be formed. The first inclined surface 310A may have an inclination of an acute angle. Acute angle means an angle between 0 and 90 degrees. For example, the acute angle may be about 60 degrees. The first support 310 may include an insulating material such as an oxide.

A first stack 320 may be formed by alternately stacking first material layers 320A and second material layers 320B on the first support 310. The first stack 320 may include a first cell region CR1 in which the second material layers 320B extend in the first direction I and a first contact region CTR1 in which the second material layers 320B extend along the first inclined surface 310A. For example, the first material layers 320A may include an insulating material such as an oxide, and the second material layers 320B may include a sacrificial material such as nitride. Subsequently, the first stack 320 may be etched to be positioned at substantially the same level as a top surface of the first support 310. Therefore, a top surface of the second material layers 320B of the first contact region CTR1 may be exposed at substantially the same level. Subsequently, a first interlayer insulating layer IL11 may be formed on the first stack 320. The first interlayer insulating layer IL11 may include an insulating material such as an oxide.

A channel sacrificial layer CHS may be formed in the first stack 320. The channel sacrificial layer CHS may extend through the first interlayer insulating layer IL11 and may be formed in the first stack 320. The channel sacrificial layer CHS may be formed in the first cell region CR1. The channel sacrificial layer CHS may include a material having an etch selectivity with respect to the first material layers 320A and the second material layers 320B. For example, the channel sacrificial layer CHS may include tungsten, titanium nitride, SiCN, or the like.

Subsequently, a second support 330 including a second inclined surface 330A may be formed on the first support 310. The second inclined surface 330A may have substantially the same inclination as the first inclined surface 310A. For example, the second inclined surface 330A may have an inclination of an acute angle. The second support 330 may include an insulating material such as an oxide.

A second stack 340 may be formed by alternately stacking third material layers 340A and fourth material layers 340B on the second support 330. The second stack 340 may include a second cell region CR2 in which the fourth material layers 340B extend in the first direction I and a second contact region CTR2 in which the fourth material layers 340B extend along the second inclined surface 330A. For example, the third material layers 340A may include an insulating material such as an oxide, and the fourth material layers 340B may include a sacrificial material such as nitride. Subsequently, the second stack 340 may be etched to be positioned at substantially the same level as a top surface of the second support 330. Therefore, a top surface of the fourth material layers 340B of the second contact region CTR2 may be exposed at substantially the same level. Subsequently, a second interlayer insulating layer IL21 may be formed on the second stack 340. The second interlayer insulating layer IL21 may include an insulating material such as an oxide.

The first stack 320 and the second stack 340 may overlap with each other. For example, in the third direction III crossing the first direction I, the first and second cell regions CR1 and CR2 may overlap with each other. In addition, in the third direction III, the first and second contact regions CTR1 and CTR2 may overlap with each other. For example, the first direction I may be a horizontal direction in which the second material layers 320B extend, and the third direction III may be a vertical direction in which the second material layers 320B are stacked. However, the present disclosure is not limited thereto, and the first cell region CR1 and the second contact region CTR2 may partially overlap, and the second cell region CR2 and the first contact region CTR1 may not overlap with each other. By overlapping the first and second cell regions CR1 and CR2 and overlapping the first and second contact regions CTR1 and CTR2, an area occupied by the first and second gate structures 120 and 140 in the semiconductor device may be reduced. Therefore, an integration degree of the semiconductor device may be improved.

For reference, an additional first interlayer insulating layer IL12 may be formed on the first interlayer insulating layer IL11 before forming the second stack 340. The additional first interlayer insulating layer IL12 may include an insulating material such as an oxide.

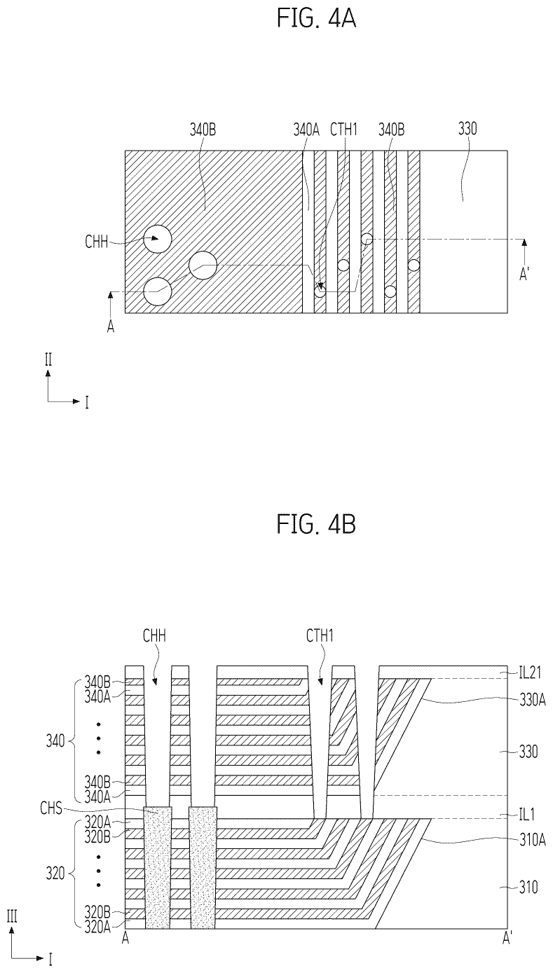

Referring now to FIGS. 4A and 4B, a channel opening CHH exposing the channel sacrificial layer CHS may be formed in the second stack 340. For example, the channel opening CHH may be formed in the second stack 340 through the second interlayer insulating layer IL21.

A first contact opening CTH1 exposing at least one second material layer 320B among the second material layers 320B may be formed in the second stack 340. The first contact opening CTH1 may also be formed in the first and second contact regions CTR1 and CTR2. When forming the channel opening CHH, the first contact opening CTH1 may also be formed. Therefore, the process time, cost and complexity may be reduced significantly by unifying a process to simultaneously form the channel opening CHH and the first contact opening CTH1.

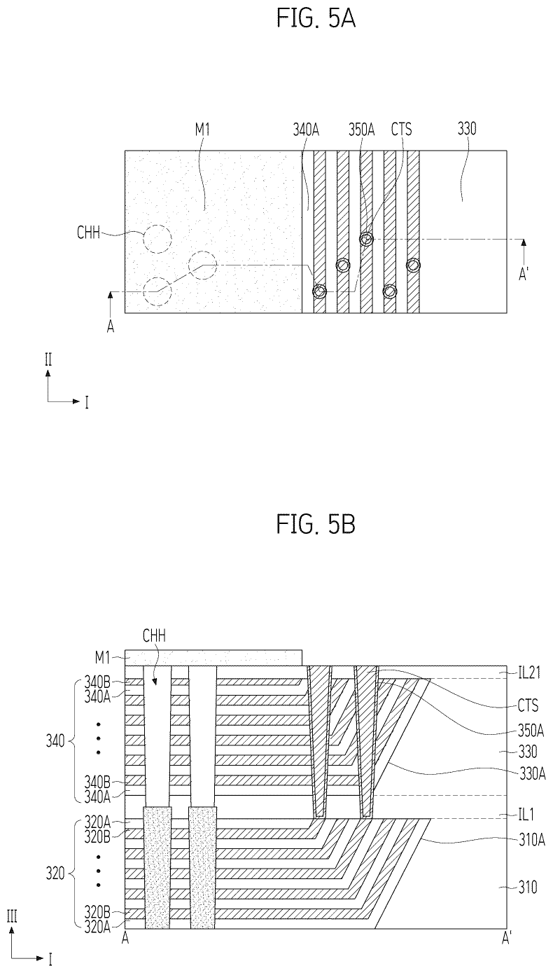

Referring now to FIGS. 5A and 5B, a first mask pattern M1 may be formed on the second stack 340. For example, the first mask pattern M1 covering the channel opening CHH and exposing the first contact opening CTH1 may also be formed. For example, the first mask pattern M1 may at least partially fill the channel opening CHH.

Subsequently, a preliminary insulating spacer 350A may be formed in the first contact opening CTH1. For example, the preliminary insulating spacer 350A may be formed in a state in which the channel opening CHH is exposed. The preliminary insulating spacer 350A may be conformally formed in the first contact opening CTH1. The preliminary insulating spacer 350A may include an insulating material such as an oxide.

Subsequently, a contact sacrificial layer CTS may be formed in the first contact opening CTH1. The contact sacrificial layer CTS may be formed to fill the first contact opening CTH1. The contact sacrificial layer CTS may include a material having an etch selectivity with respect to the second material layers 320B. For example, the contact sacrificial layer CTS may include SiCN or the like.

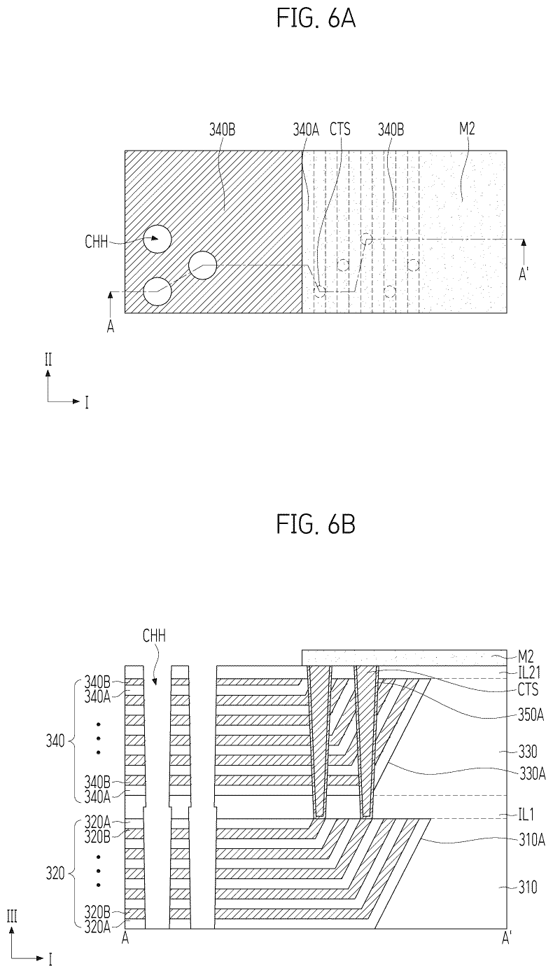

Referring now to FIGS. 6A and 6B, a second mask pattern M2 may be formed on the second stack 340. Before forming the second mask pattern M2, the first mask pattern M1 may be removed. The second mask pattern M2 may cover the contact sacrificial layer CTS and expose the channel opening CHH. Subsequently, the channel sacrificial layer CHS may be removed through the channel opening CHH to extend the channel opening CHH.

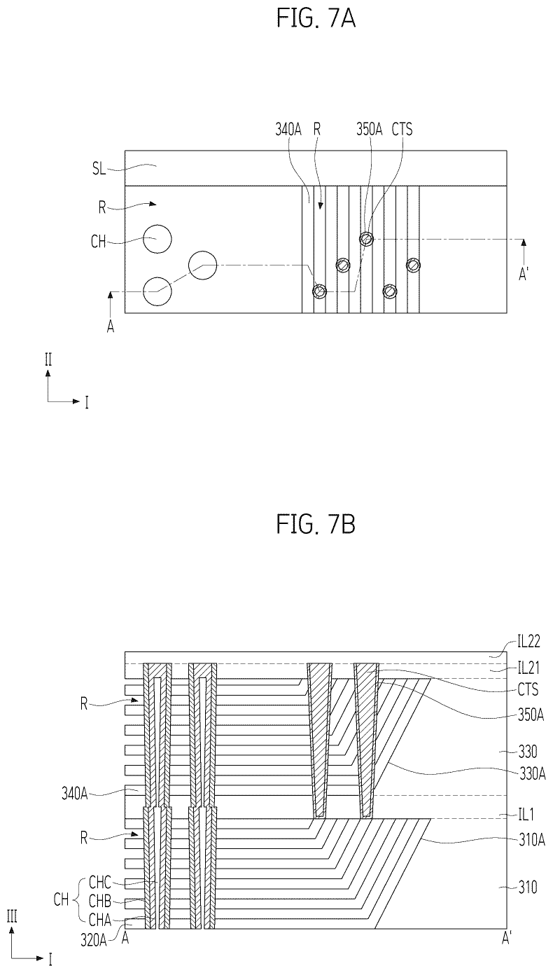

Referring now to FIGS. 7A and 7B, the channel structure CH may be formed in the channel opening CHH. The channel structure CH may include the channel layer CHA. The channel structure CH may include the memory layer CHB surrounding the channel layer CHA and the insulating core CHC in the channel layer CHA. Subsequently, the second mask pattern M2 may be removed.

Subsequently, the slit SL extending through the second stack 340 and the first stack 320 may be formed. The slit SL may extend in the first direction I. Subsequently, recesses R may be formed by removing the second material layers 320B and the fourth material layers 340B through the slit SL.

For reference, before forming the slit SL, an additional second interlayer insulating layer IL22 may be formed. The additional second interlayer insulating layer IL22 may cover the channel structure CH and the contact sacrificial layer CTS. The additional second interlayer insulating layer IL22 may include an insulating material such as an oxide.

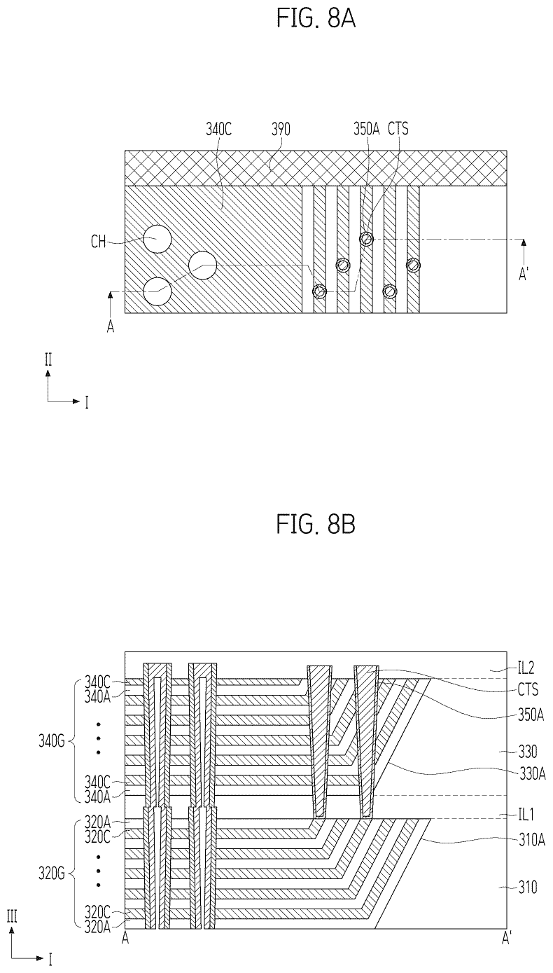

Referring now to FIGS. 8A and 8B, fifth material layers 320C and 340C may be formed in the recesses R. Therefore, a first gate structure 320G including first material layers 320A and fifth material layers 320C alternately stacked may be formed. A second gate structure 340G including third material layers 340A and fifth material layers 340C alternately stacked may be formed. For example, the fifth material layers 320C and 340C may be used as a gate line of the gate structures 320G and 340G and may include a conductive material such as tungsten.

A slit structure 390 may be formed in the slit SL. The slit structure 390 may be an insulating layer including an insulating material such as an oxide. Alternatively, the slit structure 390 may include a source contact structure connected to the source structure. For reference, the first interlayer insulating layer IL11 and the additional first interlayer insulating layer IL12 may be used as the first interlayer insulating layer IL1, and the second interlayer insulating layer IL21 and the additional second interlayer insulating layer IL22 may be used as the second interlayer insulating layer IL2.

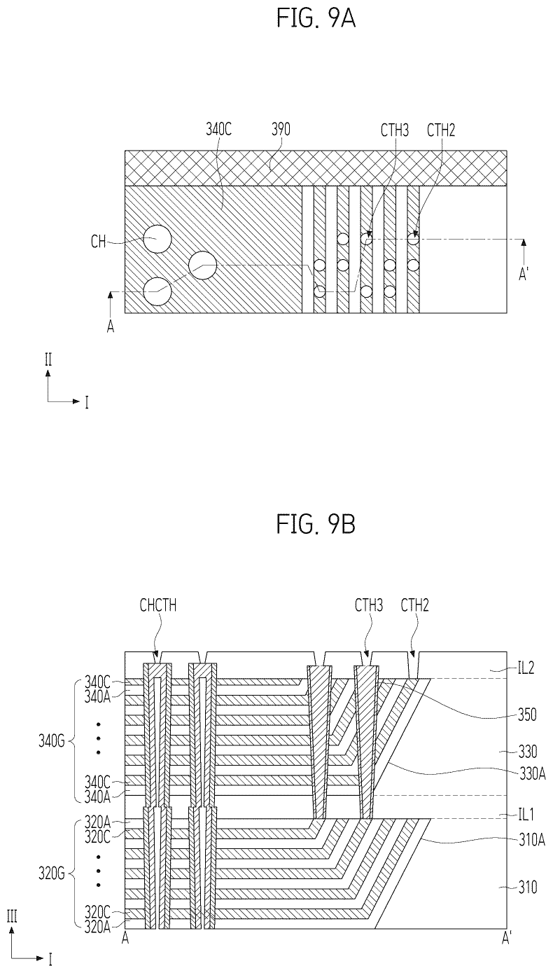

Referring now to FIGS. 9A and 9B, a third contact opening CTH3 exposing the contact sacrificial layer CTS may be formed. For example, the third contact opening CTH3 extending through the second interlayer insulating layer IL2 and exposing the contact sacrificial layer CTS may be formed.

A second contact opening CTH2 exposing at least one fifth material layer 340C among the fifth material layers 340C of the second gate structure 340G may be exposed. When forming the second contact opening CTH2, the third contact opening CTH3 may also be formed.

A channel contact opening CHCTH exposing the channel structure CH may be formed. For example, the channel contact opening HCTH exposing the channel layer CHA may be formed. When forming the third contact opening CTH3 or the second contact opening CTH2, the channel contact opening CHCTH may be formed. Therefore, a process time and a process cost may be reduced by forming in a single operation the second contact opening CTH2, the third contact opening CTH3, or the channel contact opening CTHH.

Subsequently, the contact sacrificial layer CTS may be removed through the third contact opening CTH3. The first contact opening CTH1 may be reopened by removing the contact sacrificial layer CTS. Subsequently, at least one fifth material layer 320C among the fifth material layers 320C of the first gate structure 320G may be exposed by removing the preliminary insulating spacer 350A formed on a lower surface of the first contact opening CTH1. Therefore, an insulating spacer 350 may be formed.

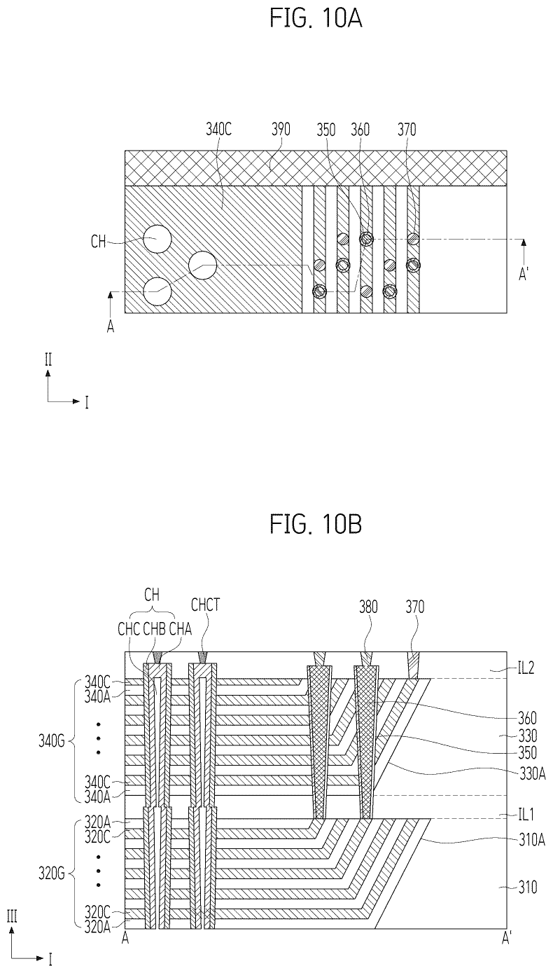

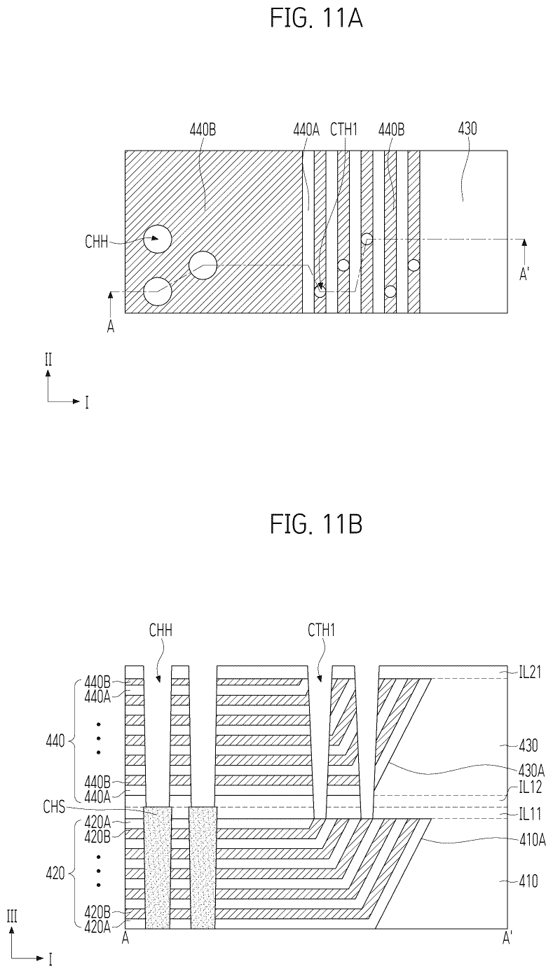

Referring now to FIGS. 10A and 10B, a first contact plug 360 may be formed in the first contact opening CTH1. A third contact plug 380 may be formed in the third contact opening CTH3. When forming the first contact plug 360, the third contact plug 380 may also be formed. For example, the first contact plug 360 or the third contact plug 380 may include a conductive material such as tungsten.

A second contact plug 370 may be formed in the second contact opening CTH2. The channel contact plug CHCT may be formed in the channel contact opening CHCTH. When forming the first contact plug 360, the second contact plug 370 or the channel contact plug CHCT may also be formed. Therefore, a process time and a process cost may be reduced by forming in a single operation the first contact plug 360, the second contact plug 370, the third contact plug 380, or the channel contact plug CHCT.

According to the manufacturing method as described above, the first contact region CTR1 of the first gate structure 320G and the second contact region CTR2 of the second gate structure 340G may overlap with each other. In addition, the first contact plug 360 extending through the second contact region CTR2 of the second gate structure 340G may be formed. Therefore, an area occupied by the first gate structure 320G and the second gate structure 340G in the semiconductor device may be reduced, and an integration degree of the semiconductor device may be improved.

When forming the channel opening CHH, the first contact opening CTH1 may also be formed. In addition, when forming the second contact opening CTH2, the third contact opening CTH3 may also be formed. In addition, when forming the first contact plug 360, the second contact plug 370 and the third contact plug 380 may also be formed. Therefore, the process time, cost and complexity may be reduced significantly by unifying the above process operations.

FIGS. 11A to 17B are diagrams illustrating a method of manufacturing a semiconductor device according to an embodiment of the present disclosure. FIGS. 11A, 12A, 13A, 14A, 15A, 16A, and 17A are plan views, and FIGS. 11B, 12B, 13B, 14B, 15B, 16B, and 17B are A-A′ cross-sectional views of each A view. Hereinafter, any content repetitive to previously described content may be omitted.

Referring now to FIGS. 11A and 11B, a first support 410 including a first inclined surface 410A may be formed. The first inclined surface 410A may have an inclination of an acute angle. The first support 410 may include an insulating material such as an oxide.

A first stack 420 may be formed by alternately stacking first material layers 420A and second material layers 420B on the first support 410. For example, the first material layers 420A may include an insulating material such as an oxide, and the second material layers 420B may include a sacrificial material such as nitride. Subsequently, the first interlayer insulating layer IL11 may be formed on the first stack 420. The first interlayer insulating layer IL11 may include an insulating material such as an oxide.

The channel sacrificial layer CHS may be formed in the first stack 420. The channel sacrificial layer CHS may extend through the first interlayer insulating layer IL11 and may be formed in the first stack 420. The channel sacrificial layer CHS may include a material having an etch selectivity with respect to the first material layers 420A and the second material layers 420B. For example, the channel sacrificial layer CHS may include tungsten, titanium nitride, SiCN, or the like.

Subsequently, a second support 430 including a second inclined surface 430A may be formed on the first support 410. The second inclined surface 430A may have an inclination of an acute angle. The second support 410 may include an insulating material such as an oxide.

A second stack 440 may be formed by alternately stacking third material layers 440A and fourth material layers 440B on the second support 430. Before forming the second stack 440, the additional first interlayer insulating layer IL12 may be formed on the first interlayer insulating layer IL11. The third material layers 440A may include an insulating material such as an oxide, and the fourth material layers 440B may include a sacrificial material such as nitride. Subsequently, the second interlayer insulating layer IL21 may be formed on the second stack 440. The second interlayer insulating layer IL21 may include an insulating material such as an oxide.

Subsequently, the channel opening CHH exposing the channel sacrificial layer CHS may be formed in the second stack 440. The first contact opening CTH1 exposing at least one second material layer 420B among the second material layers 420B may be formed in the second stack 440. When forming the channel opening CHH, the first contact opening CTH1 may also be formed.

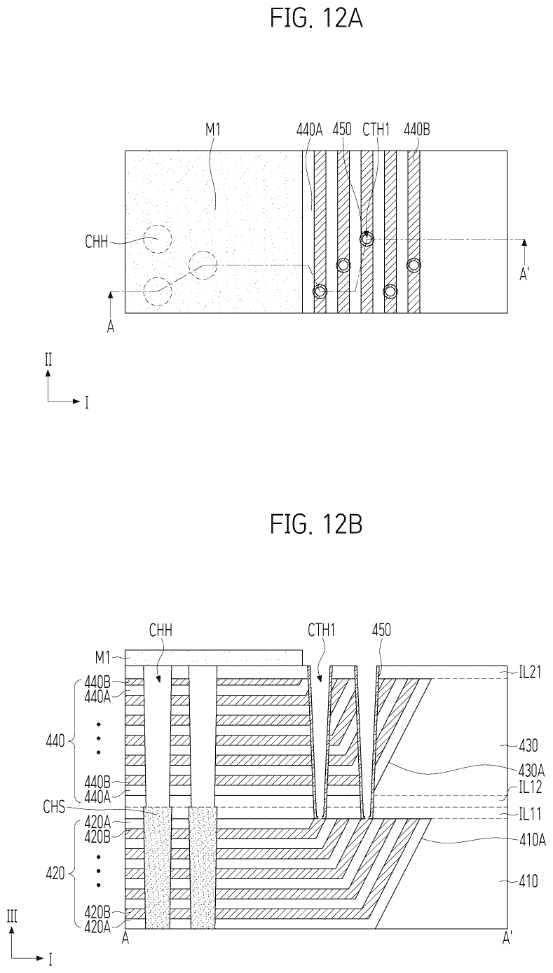

Referring to FIGS. 12A and 12B, the first mask pattern M1 may be formed on the second stack 440. For example, the first mask pattern M1 covering the channel opening CHH and exposing the first contact opening CTH1 may also be formed. Subsequently, a preliminary insulating spacer (not shown) may be formed in the first contact opening CTH1. The preliminary insulating spacer may be conformally formed in the first contact opening CTH1. Subsequently, at least one second material layer 420B among the second material layers 420B may be exposed by removing the preliminary insulating spacer formed on the lower surface of the first contact opening CTH1. Therefore, the insulating spacer 450 may be formed on a sidewall of the first contact opening CTH1.

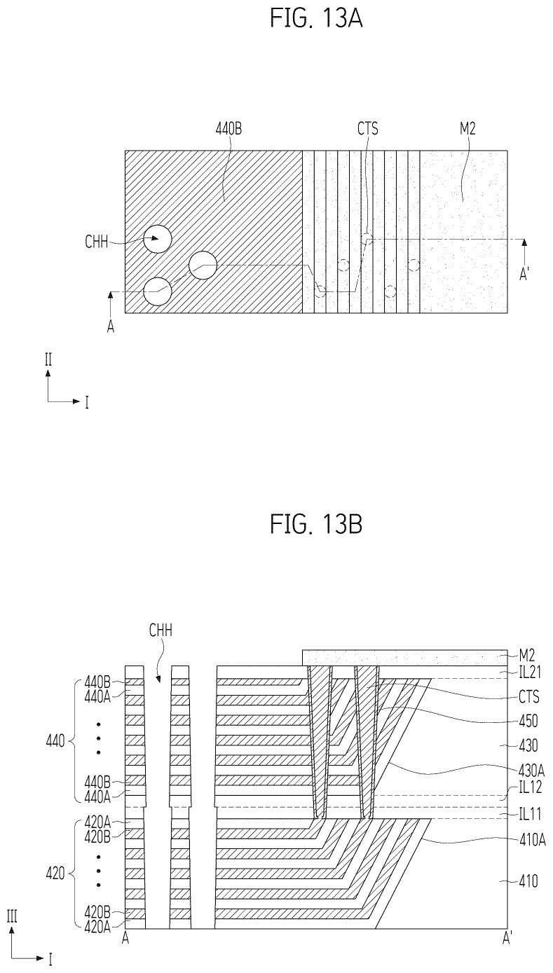

Referring now to FIGS. 13A and 13B, the contact sacrificial layer CTS may be formed in the first contact opening CTH1. The contact sacrificial layer CTS may be formed to fill the first contact opening CTH1. The contact sacrificial layer CTS may include a material having an etch selectivity with respect to the first material layers 420A. The contact sacrificial layer CTS may include a material having an etch rate substantially equal or similar to that of the second material layers 420B. For example, the contact sacrificial layer CTS may include substantially the same material as the second material layers 420B. The contact sacrificial layer CTS may be connected to at least one second material layer 420B among the second material layers 420B. This is because the contact sacrificial layer CTS is formed in a state in which the lower surface of the first contact opening CTH1 is opened.

Subsequently, the second mask pattern M2 may be formed on the second stack 440. Before forming the second mask pattern M2, the first mask pattern M1 may be removed. The second mask pattern M2 may cover the contact sacrificial layer CTS and expose the channel opening CHH. Subsequently, the channel sacrificial layer CHS may be removed through the channel opening CHH to extend the channel opening CHH.

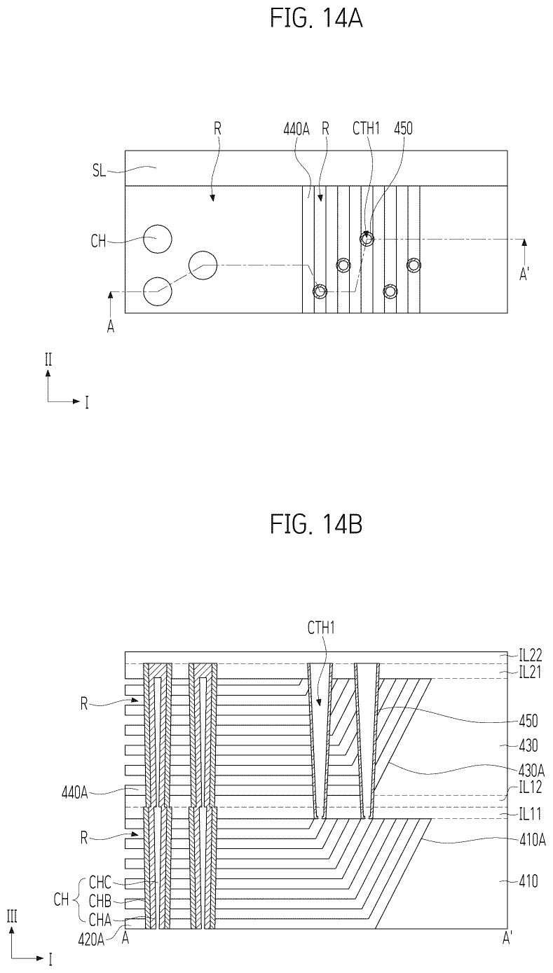

Referring now to FIGS. 14A and 14B, the channel structure CH may be formed in the channel opening CHH. The channel structure CH may include the channel layer CHA. The channel structure CH may include the memory layer CHB surrounding the channel layer CHA and the insulating core CHC in the channel layer CHA. Subsequently, the second mask pattern M2 may be removed.

Subsequently, the additional second interlayer insulating layer IL22 may be formed. The additional second interlayer insulating layer IL22 may be for covering the channel structure CH and the contact sacrificial layer CTS. The additional second interlayer insulating layer IL22 may include an insulating material such as an oxide.

Subsequently, the slit SL extending through the second stack 440 and the first stack 420 may be formed. The slit SL may extend in the first direction I. Subsequently, the recesses R may be formed by removing the second material layers 420B and the fourth material layers 440B through the slit SL. The first contact opening CTH1 may be reopened by removing the contact sacrificial layer CTS through the slit SL. Because the second material layers 420B, the fourth material layers 440B, and the contact sacrificial layer CTS include substantially the same material, the second material layers 420B, the fourth material layers 440B, and the contact sacrificial layer CTS may be simultaneously removed. That is, the second material layers 420B, the fourth material layers 440B, and the contact sacrificial layer CTS may be removed through the slit SL. For example, at least one recess R among the recesses R and the first contact opening CTH1 may be connected. Because a process of additionally removing the contact sacrificial layer CTS may be omitted, a process time and a process cost may be reduced.

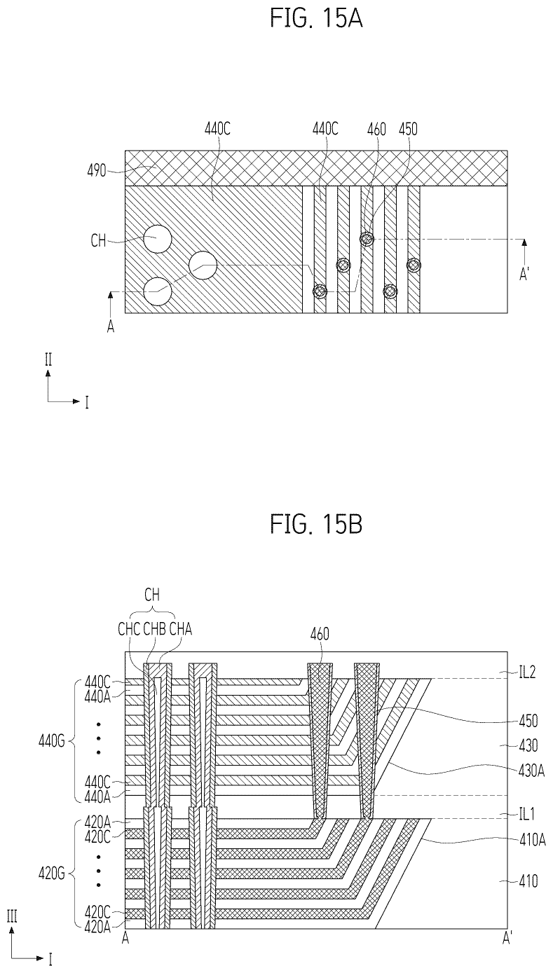

Referring now to FIGS. 15A and 15B, a first contact plug 460 may be formed by forming a fifth material layer 420C in the first contact opening CTH1. For example, the fifth material layer 420C may be formed in the first contact opening CTH1 through the slit SL. For example, the fifth material layer 420C may include a conductive material such as tungsten.

Fifth material layers 420C and 440C may be formed in the recesses R. For example, the fifth material layers 420C may be formed in the recesses R through the slit SL. Therefore, a first gate structure 420G including the first material layers 420A and the fifth material layers 420C alternately stacked may be formed. A second gate structure 440G including the first material layers 440A and the fifth material layers 440C alternately stacked may be formed.

The recess R and the first contact opening CTH1 connected to the recess R may be simultaneously filled with the fifth material layers 420C and 440C. For example, among the fifth material layers 420C and 440C, the fifth material layers 420C and 440C formed in the gate structures 420G and 440G may be used as the gate line, and the fifth material layer 420C formed in the first contact opening CTH1 may be used as the first contact plug 460. Therefore, a process time and a process cost may be reduced by forming the first contact plug 460 by utilizing a process of replacing the second material layers 420B and the fourth material layers 440B with the fifth material layers 420C and 440C.

A slit structure 490 may be formed in the slit SL. The slit structure 490 may be an insulating layer including an insulating material such as an oxide. Alternatively, the slit structure 490 may include a source contact structure connected to the source structure. For reference, the first interlayer insulating layer IL11 and the additional first interlayer insulating layer IL12 may be defined as the first interlayer insulating layer IL1, and the second interlayer insulating layer IL21 and the additional second interlayer insulating layer IL22 may be defined as the second interlayer insulating layer IL2.

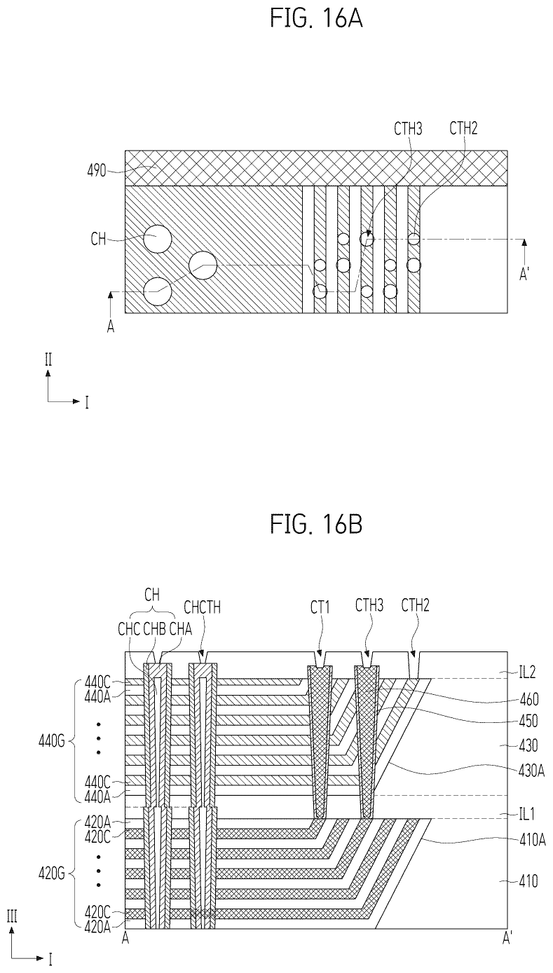

Referring now to FIGS. 16A and 16B, the third contact opening CTH3 exposing the first contact plug 460 may be formed. The second contact opening CTH2 exposing at least one fifth material layer 440C among the fifth material layers 440C of the second gate structure 440G may be exposed. The channel contact opening CHCTH exposing the channel structure CH may be formed. When forming the third contact opening CTH3 or the second contact opening CTH2, the channel contact opening CHCTH may also be formed.

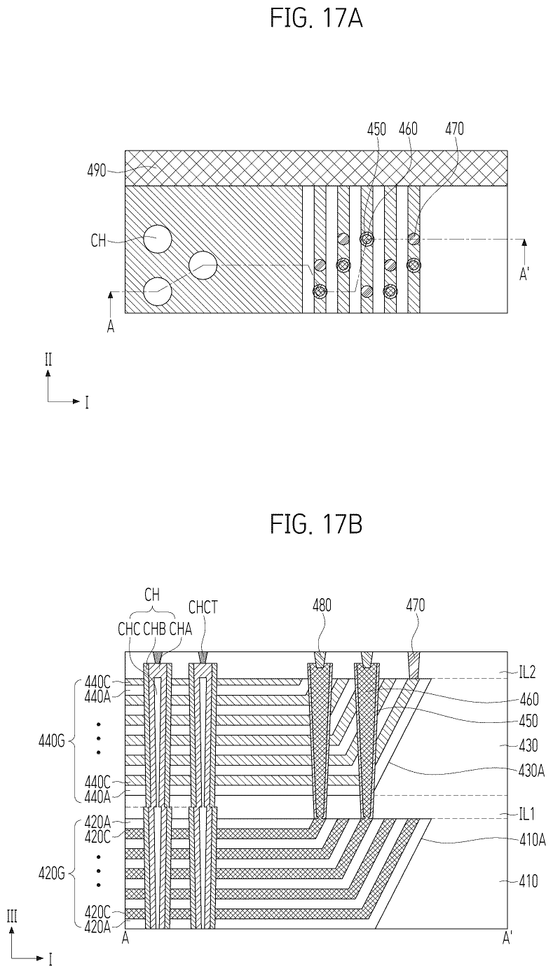

Referring now to FIGS. 17A and 17B, a third contact plug 480 may be formed in the third contact opening CTH3. A second contact plug 470 may be formed in the second contact opening CTH2. The channel contact plug CHCT may be formed in the channel contact opening CHCTH. When forming the third contact plug 480, the second contact plug 470 or the channel contact plug CHCT may also be formed. For example, the second contact plug 470, the third contact plug 480, or the channel contact plug CHCT may include a conductive material such as tungsten.

According to the manufacturing method as described above, when the gate structures 420G and 440G are formed by forming the fifth material layers 420C in the recesses R, the first contact plug 460 may be formed by forming the fifth material layers 420C in the first contact opening CTH1. In addition, when forming the third contact opening CTH3, the second contact opening CTH2 may also be formed. Therefore, a process time and a process cost may be reduced by unifying the above operations of the process.

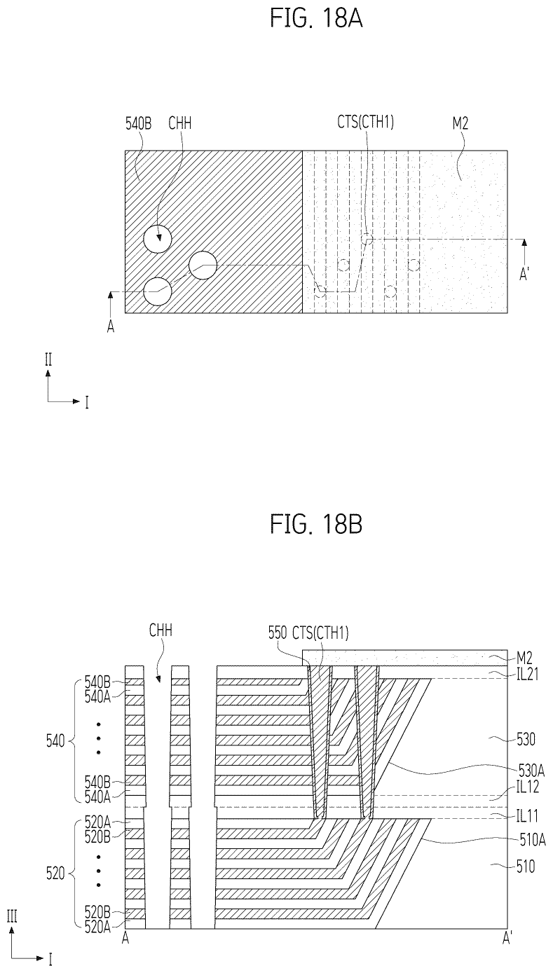

FIGS. 18A to 22B are diagrams illustrating a method of manufacturing a semiconductor device according to an embodiment of the present disclosure. FIGS. 18A, 19A, 20A, 21A, and 22A are plan views, and FIGS. 18B, 19B, 20B, 21b, and 22B are A-A′ cross-sectional views of each a view. Hereinafter, any content repetitive to previously described content may be omitted.

Referring now to FIGS. 18A and 18B, a first support 510 including a first inclined surface 510A may be formed. The first inclined surface 510A may have an inclination of an acute angle. The first support 510 may include an insulating material such as an oxide.

A first stack 520 may be formed by alternately stacking first material layers 520A and second material layers 520B on the first support 510. For example, the first material layers 520A may include an insulating material such as an oxide, and the second material layers 520B may include a sacrificial material such as nitride. Subsequently, the first interlayer insulating layer IL11 may be formed on the first stack 520. The first interlayer insulating layer IL11 may include an insulating material such as an oxide.

The channel sacrificial layer (not shown) may be formed in the first stack 520. Subsequently, a second support 530 including a second inclined surface 530A may be formed on the first support 510. The second inclined surface 530A may have an inclination of an acute angle. The second support 530 may include an insulating material such as an oxide.

A second stack 540 may be formed by alternately stacking third material layers 540A and fourth material layers 540B on the second support 530. Before forming the second stack 540, the additional first interlayer insulating layer IL12 may be formed on the first interlayer insulating layer IL11. The third material layers 540A may include an insulating material such as an oxide, and the fourth material layers 540B may include a sacrificial material such as nitride. Subsequently, the second interlayer insulating layer IL21 may be formed on the second stack 540. The second interlayer insulating layer IL21 may include an insulating material such as an oxide.

Thereafter, the channel opening CHH exposing the channel sacrificial layer may be formed in the second stack 540. The first contact opening CTH1 exposing at least one second material layer 520B among the second material layers 520B may be formed in the second stack 540. When forming the channel opening CHH, the first contact opening CTH1 may also be formed.

The first mask pattern (not shown) covering the channel opening CHH and exposing the first contact opening CTH1 may also be formed. Subsequently, the preliminary insulating spacer (not shown) may be formed in the first contact opening CTH1. Subsequently, at least one second material layer 520B among the second material layers 520B may be exposed by removing the preliminary insulating spacer formed on the lower surface of the first contact opening CTH1. Therefore, an insulating spacer 550 may be formed on the sidewall of the first contact opening CTH1.

Subsequently, the contact sacrificial layer CTS may be formed in the first contact opening CTH1. The contact sacrificial layer CTS may be formed to fill the first contact opening CTH1. The contact sacrificial layer CTS may include substantially the same material as the second material layers 520B. Therefore, the contact sacrificial layer CTS may be connected to at least one second material layer 520B among the second material layers 520B.

Subsequently, the second mask pattern M2 may be formed on the second stack 540. Before forming the second mask pattern M2, the first mask pattern may be removed. The second mask pattern M2 may cover the contact sacrificial layer CTS and expose the channel opening CHH. Subsequently, the channel opening CHH may be extended by removing the channel sacrificial layer through the channel opening CHH.

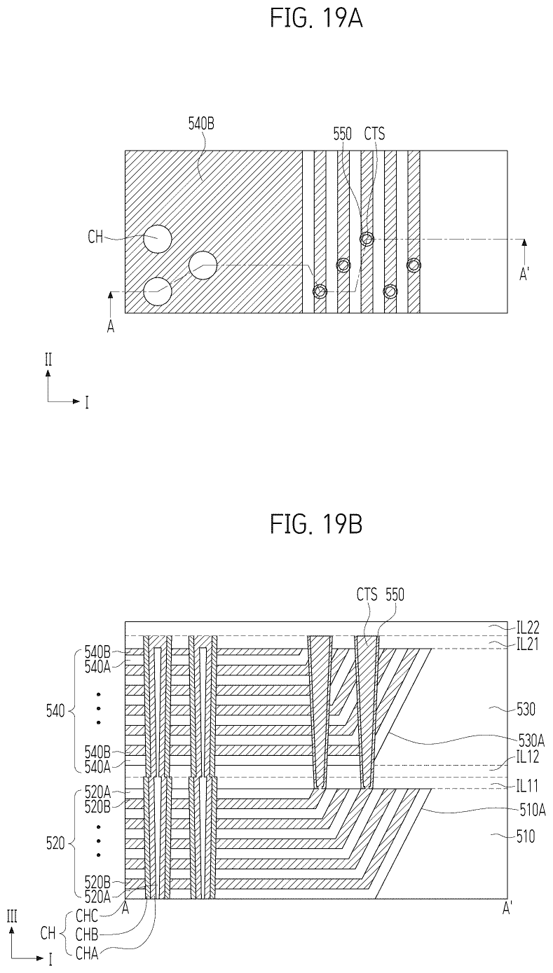

Referring now to FIGS. 19A and 19B, the channel structure CH may be formed in the channel opening CHH. The channel structure CH may include the channel layer CHA. The channel structure CH may include the memory layer CHB surrounding the channel layer CHA and the insulating core CHC in the channel layer CHA. Subsequently, the second mask pattern M2 may be removed.

Subsequently, the additional second interlayer insulating layer IL22 may be formed. The additional second interlayer insulating layer IL22 may cover the channel structure CH and the contact sacrificial layer CTS. The additional second interlayer insulating layer IL22 may include an insulating material such as an oxide.

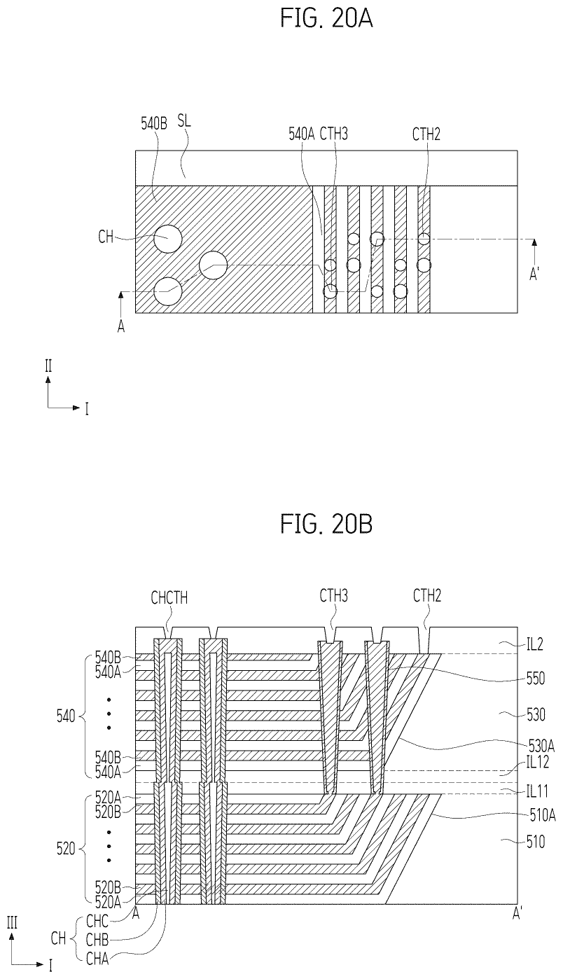

Referring now to FIGS. 20A and 20B, the slit SL extending through the second stack 540 and the first stack 520 may be formed. The slit SL may extend in the first direction I.

The third contact opening CTH3 exposing the contact sacrificial layer CTS may be formed. The second contact opening CTH2 exposing at least one fourth material layer 540B among the fourth material layers 540B may be formed. The channel contact opening CHCTH exposing the channel structure CH may be formed. When forming the third contact opening CTH3, the second contact opening CTH2 or the channel contact opening CTH3 may also be formed.

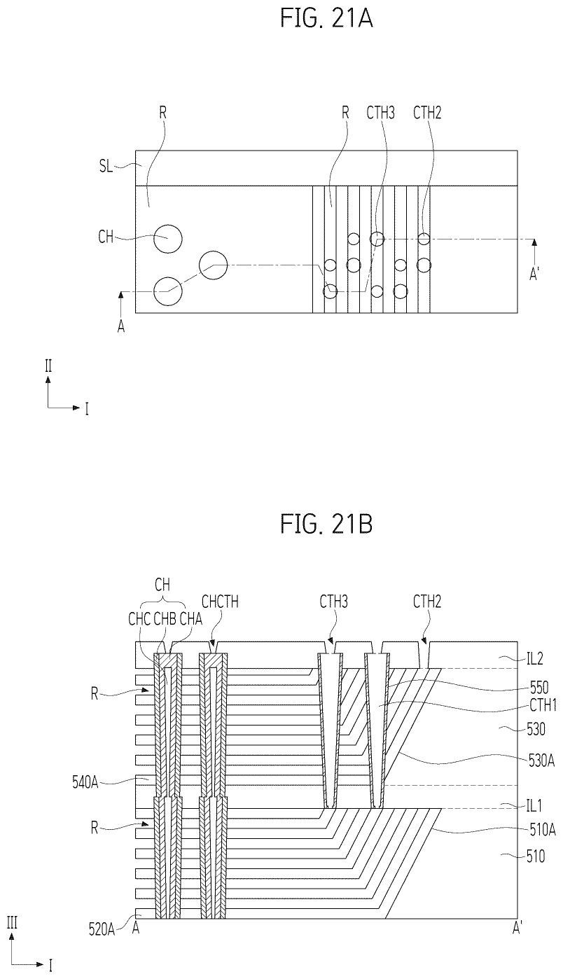

Referring now to FIGS. 21A and 21B, the recesses R may be formed by removing the second material layers 520B and the fourth material layers 540B through the slit SL. The first contact opening CTH1 may be reopened by removing the contact sacrificial layer CTS through the slit SL. For example, the contact sacrificial layer CTS or at least one second material layer 520B among the second material layers 520B may be removed through the third contact opening CTH3. At least one fourth material layer 540B among the fourth material layers 540B may be removed through the second contact opening CTH2. That is, the second material layers 520B and the contact sacrificial layer CTS may be removed through the slit SL and the third contact opening CTH3. The fourth material layers 540B may be removed through the slit SL and the second contact opening CTH2. At least one recess R among the recesses R, the first contact opening CTH1, and the third contact opening CTH3 may be connected to each other, and at least one recess R among the recesses R and the second contact opening CTH2 may be connected to each other. Therefore, because the second material layer 520B and the contact sacrificial layer CTS may be removed from one end to another end through the slit SL and the second material layer 520B and the contact sacrificial layer CTS may be removed from another end to one end through the third contact opening CTH3, a process time and a process cost may be reduced by removing the second material layer 520B and the contact sacrificial layer CTS at a speed higher than that of a case where the second material layer 520B and the contact sacrificial layer CTS are removed in one direction.

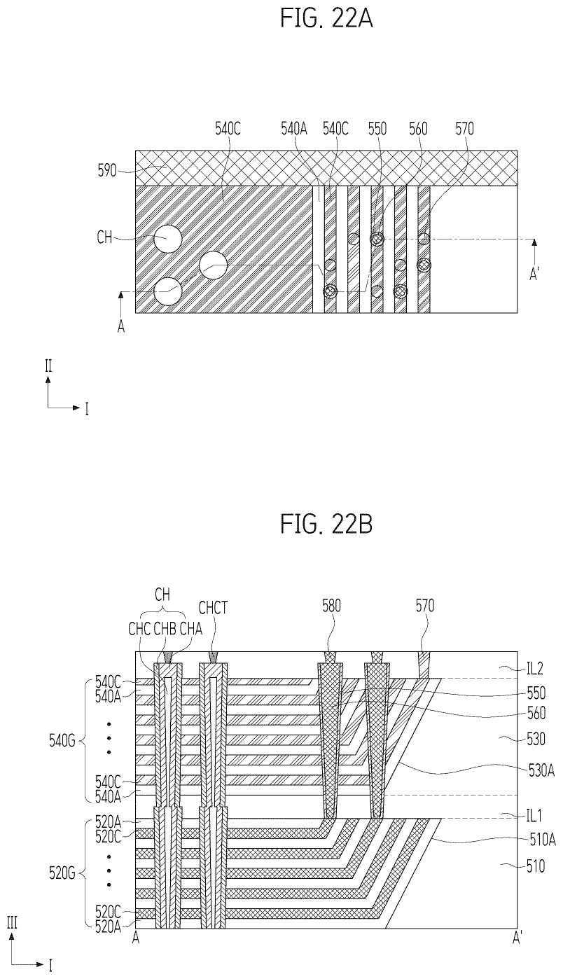

Referring now to FIGS. 22A and 22B, a first contact plug 560 may be formed by forming a fifth material layer 520C in the first contact opening CTH1. A third contact plug 580 may be formed by forming the fifth material layer 520C in the third contact opening CTH3. For example, the first contact plug 560 and the third contact plug 580 may be formed by forming the fifth material layer 520C in the first contact opening CTH1 and the third contact opening CTH3 through the slit SL. For example, the fifth material layer 520C may include a conductive material such as tungsten.

Fifth material layers 520C and 540C may be formed in the recesses R. For example, the fifth material layers 520C may be formed in the recesses R through the slit SL, the second contact opening CTH2, and the third contact opening CTH3. Therefore, a first gate structure 520G including the first material layers 520A and the fifth material layers 520C alternately stacked may be formed. A second gate structure 540G including the first material layers 540A and the fifth material layers 540C alternately stacked may be formed.

A second contact plug 570 may be formed in the second contact opening CTH2. The channel contact plug CHCT may be formed in the channel contact opening CHCTH. When forming the first contact plug 560 or the third contact plug 580, the second contact plug 570 or the channel contact plug CHCT may also be formed.

The recess R, the first contact opening CTH1 connected to the recess R, the third contact opening CTH3 connected to the first contact opening CTH1, and the second contact opening CTH2 connected to the recess R may be simultaneously filled with the fifth material layers 520C and 540C. Among the fifth material layers 520C and 540C, the fifth material layers 520C and 540C formed in the gate structures 520G and 540G may be used as the gate line, the fifth material layer 520C formed in the first contact opening CTH1 may be used as the first contact plug 560, and the fifth material layer 520C formed in the third contact opening CTH3 may be used as the third contact plug 580. The fifth material layer 540C formed in the second contact opening CTH2 may be used as the second contact plug 570.

A slit structure 590 may be formed in the slit SL. The slit structure 590 may be an insulating layer including an insulating material such as an oxide. Alternatively, the slit structure 590 may include a source contact structure connected to the source structure. For reference, the first interlayer insulating layer IL11 and the additional first interlayer insulating layer IL12 may be defined as the first interlayer insulating layer IL1, and the second interlayer insulating layer IL21 and the additional second interlayer insulating layer IL22 may be defined as the second interlayer insulating layer IL2.

According to the manufacturing method as described above, the second material layer 520B and the contact sacrificial layer CTS may be removed through the slit SL and the third contact opening CTH3. In addition, the first contact plug 560 may be formed through the slit SL and the third contact opening CTH3. Therefore, because a process may be performed at a speed higher than a case where the process is performed through the slit SL or the third contact opening CTH3, a process time and a process cost may be reduced.

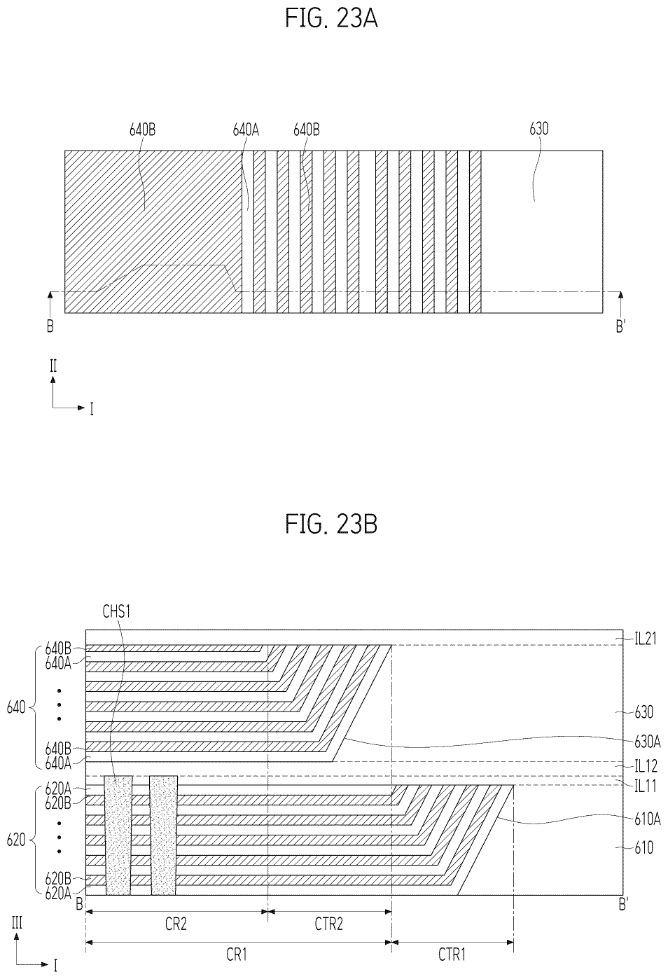

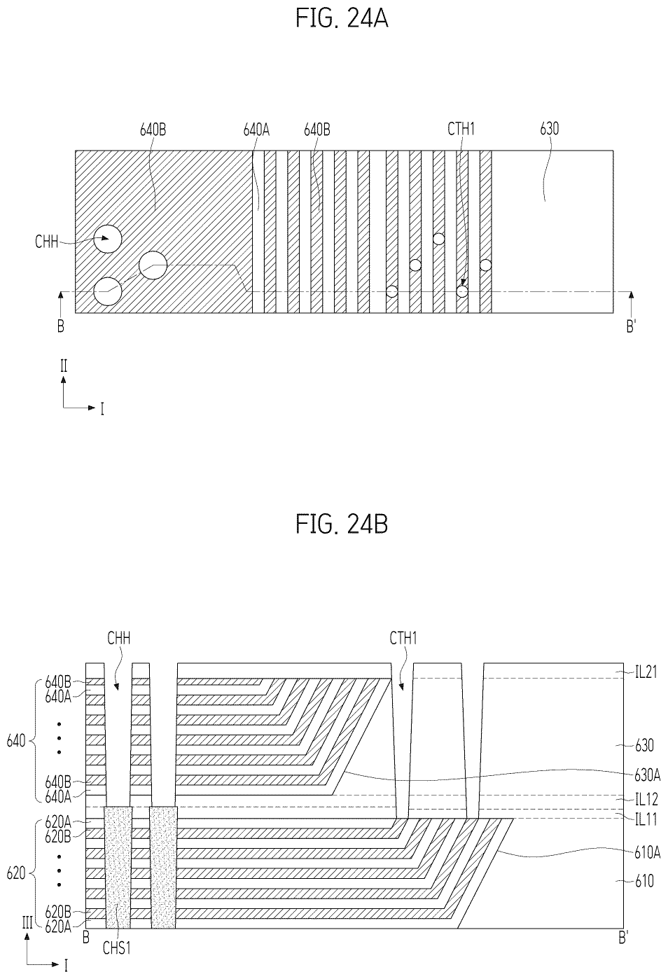

FIGS. 23A to 28B are diagrams illustrating a method of manufacturing a semiconductor device according to an embodiment of the present disclosure. FIGS. 23A, 24A, 25A, 26A, 27A, and 28A are plan views, and FIGS. 23B, 24B, 25B, 26B, 27B, and 28B may be B-B′ cross-sectional views of each A view. Hereinafter, any content repetitive to previously described content may be omitted.

Referring now to FIGS. 23A and 23B, a first support 610 including a first inclined surface 610A may be formed. The first inclined surface 610A may have an inclination of an acute angle.

A first stack 620 may be formed by alternately stacking first material layers 620A and second material layers 620B on the first support 610. The first stack 620 may include a first contact region CTR1 in which the second material layers 620B extend in the first direction I and a first contact region in which the second material layers 620B extend along the first inclined surface 610A. Subsequently, the first stack 620 may be etched to be positioned at substantially the same level as a top surface of the first support 610. Therefore, a top surface of the second material layers 620B of the first contact region CTR1 may be exposed at substantially the same level. Subsequently, the first interlayer insulating layer IL11 may be formed on the first stack 620.

A first channel sacrificial layer CHS1 may be formed in the first stack 620. The first channel sacrificial layer CHS may be formed in the first cell region CR1. The first channel sacrificial layer CHS may include a material having an etch selectivity with respect to the first material layers 620A and the second material layers 620B.

Subsequently, a second support 630 including a second inclined surface 630A may be formed on the first support 610. The second inclined surface 630A may have substantially the same inclination as the first inclined surface 610A.

The second stack 640 may be formed by alternately stacking third material layers 640A and fourth material layers 640B on the second support 630. The second stack 640 may include a second cell region CR2 in which the fourth material layers 640B extend in the first direction I and a second contact region CTR2 in which the fourth material layers 640B extend along the second inclined surface 630A. Subsequently, the second stack 640 may be etched to be positioned at substantially the same level as a top surface of the second support 630. Therefore, a top surface of the fourth material layers 640B of the second contact region CTR2 may be exposed at substantially the same level. Subsequently, the second interlayer insulating layer IL21 may be formed on the second stack 640.

The first stack 620 and the second stack 640 may overlap with each other. For example, in the third direction III crossing the first direction I, the first cell region CR1 may overlap with second cell region CR2 and the second contact region CTR2. The first contact region CTR1 may not overlap with second cell region CR2 and the second contact region CTR2. For example, the first direction I may be a horizontal direction in which the second material layers 620B extend, and the third direction III may be a vertical direction in which the second material layers 620B are stacked. However, the present disclosure is not limited thereto, and the first and second contact regions CTR1 and CTR2 may not overlap with each other. For reference, before forming the second stack 640, the additional first interlayer insulating layer IL12 may be formed on the first interlayer insulating layer IL11. Subsequently, the second interlayer insulating layer IL21 may be formed on the second stack 640.

Referring now to FIGS. 24A and 24B, the channel opening CHH exposing the first channel sacrificial layer CHS1 may be formed in the second stack 640. The first contact opening CTH1 exposing at least one second material layer 620B among the second material layers 620B may be formed in the second support 630. The first contact opening CTH1 may also be formed in the first contact region CTR1. When forming the channel opening CHH, the first contact opening CTH1 may also be formed. Therefore, the process time, cost and complexity may be reduced significantly by unifying a process to simultaneously form the channel opening CHH and the first contact opening CTH1.

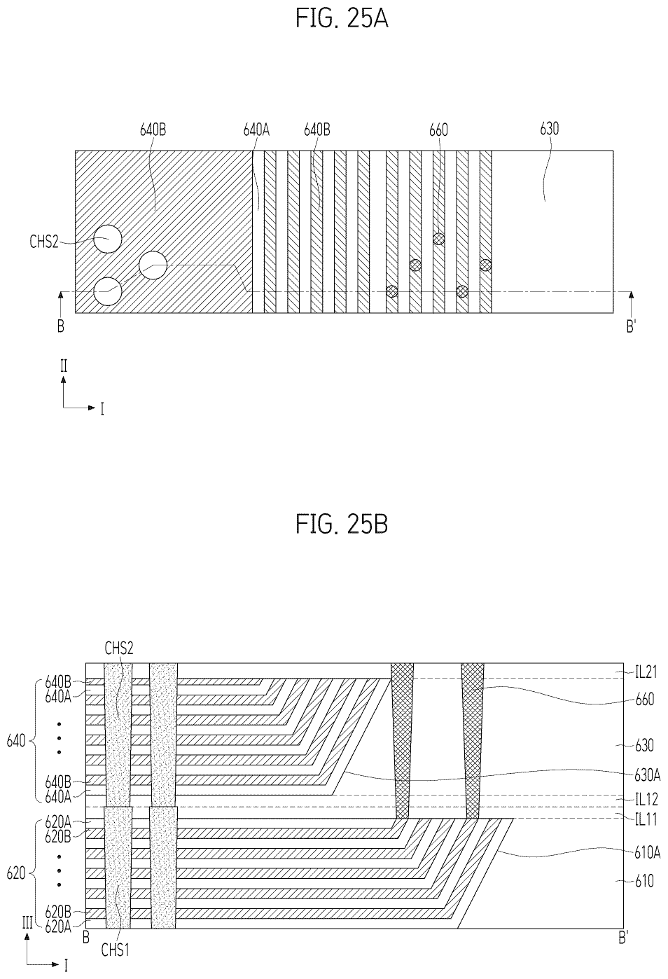

Referring now to FIGS. 25A and 25B, a second channel sacrificial layer CHS2 may be formed in the channel opening CHH. For example, the second channel sacrificial layer CHS2 may include a material having an etch selectivity with respect to the third material layers 620A and the fourth material layers 620B. For example, the second channel sacrificial layer CHS2 may include substantially the same material as the first channel sacrificial layer CHS1. The second channel sacrificial layer CHS2 may include a sacrificial material such as tungsten.

A first contact plug 660 may be formed in the first contact opening CTH1. When forming the second channel sacrificial layer CHS2, the first contact plug 660 may also be formed. The process time, cost and complexity may be reduced significantly by forming in a single operation the second channel sacrificial layer CHS2 and a process of forming the first contact plug 660. Because the first contact plug 660 extends through the second support 630, a separate insulating spacer is not required. The first contact plug 660 may include a material having an etch selectivity with respect to the second material layer 620B. For example, the first contact plug 660 may include a conductive material such as tungsten.

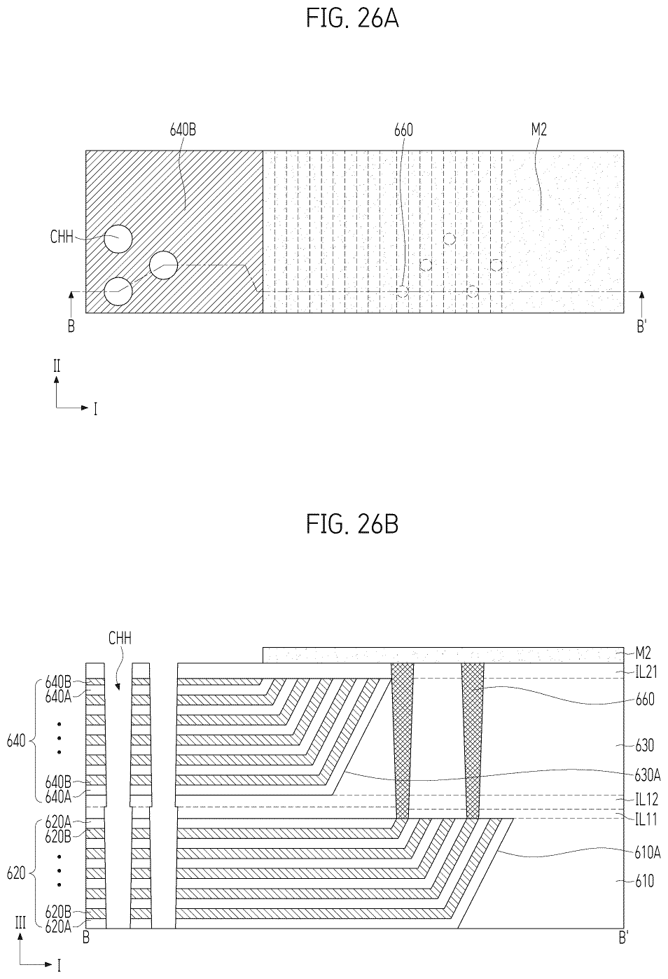

Referring now to FIGS. 26A and 26B, the second mask pattern M2 may be formed on the second stack 640. The second mask pattern M2 may cover the first contact plug 660 and expose the second channel sacrificial layer CHS2. Subsequently, the channel opening CHH may be reopened by removing the second channel sacrificial layer CHS2 and the first channel sacrificial layer CHS1.

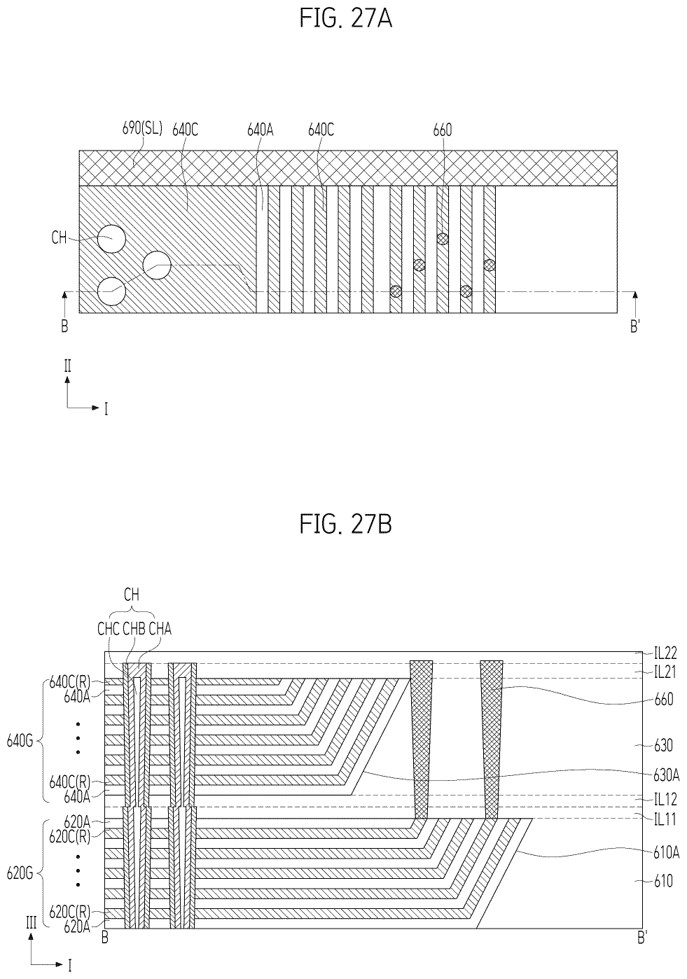

Referring now to FIGS. 27A and 27B, the channel structure CH may be formed in the channel opening CHH. The channel structure CH may include the channel layer CHA. The channel structure CH may include the memory layer CHB surrounding the channel layer CHA and the insulating core CHC in the channel layer CHA. Subsequently, the second mask pattern M2 may be removed.

Subsequently, the slit SL extending through the second stack 640 and the first stack 620 may be formed. The slit SL may extend in the first direction I. Subsequently, the recesses R may be formed by removing the second material layers 620B and the fourth material layers 640B through the slit SL. For reference, before forming the slit SL, the additional second interlayer insulating layer IL22 may be formed.

Fifth material layers 620C and 640C may be formed in the recesses R. Therefore, a first gate structure 620G including the first material layers 620A and the fifth material layers 620C alternately stacked may be formed. A second gate structure 640G including the first material layers 640A and the fifth material layers 640C alternately stacked may be formed. For example, at least one fifth material layer 620C among the fifth material layers 620C of the first gate structure 620G may be connected to the first contact plug 660. The fifth material layers 620C and 640C may be used as the gate line of the gate structures 620G and 640G and may include a conductive material such as tungsten.

A slit structure 690 may be formed in the slit SL. The slit structure 690 may be an insulating layer including an insulating material such as an oxide. Alternatively, the slit structure 690 may include a source contact structure connected to the source structure. For reference, the first interlayer insulating layer IL11 and the additional first interlayer insulating layer IL12 may be used as the first interlayer insulating layer IL1, and the second interlayer insulating layer IL21 and the additional second interlayer insulating layer IL22 may be used as the second interlayer insulating layer IL2.

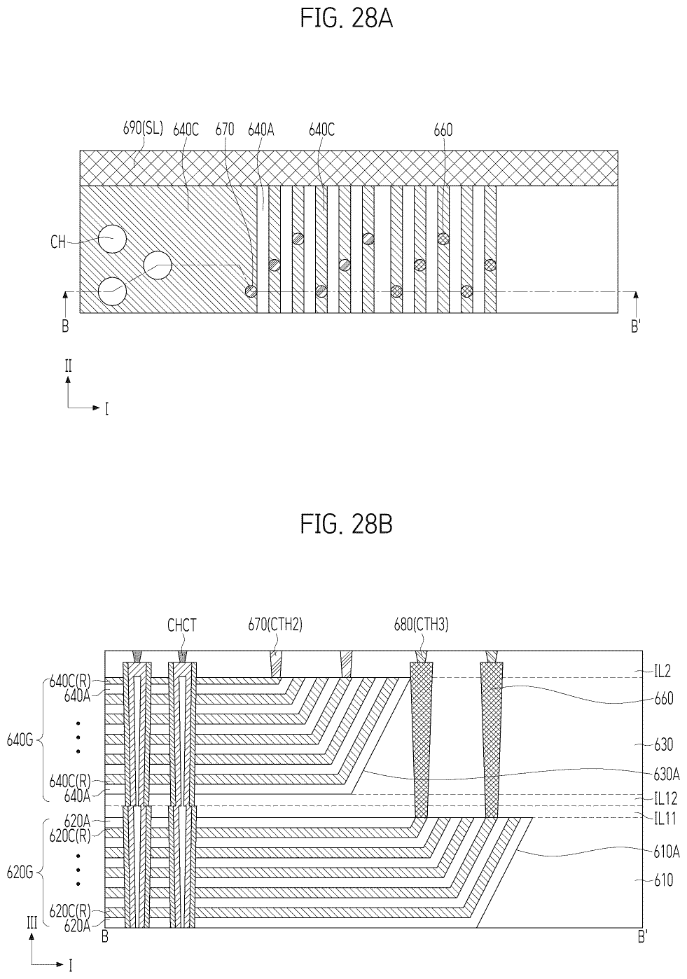

Referring now to FIGS. 28A and 28B, the third contact opening CTH3 exposing the first contact plug 660 may be formed. The second contact opening CTH2 exposing at least one fifth material layer 640C among the fifth material layers 640C of the second gate structure 640G may be exposed. When forming the second contact opening CTH2, the third contact opening CTH3 may also be formed. The channel contact opening CHCTH exposing the channel structure CH may be formed. When forming the third contact opening CTH3 or the second contact opening CTH2, the channel contact opening CHCTH may also be formed. Therefore, a process time and a process cost may be reduced by forming in a single operation the second contact opening CTH2, the third contact opening CTH3, or the channel contact opening CTHH.

Subsequently, a third contact plug 680 may be formed in the third contact opening CTH3. The third contact plug 680 may be connected to the first contact plug 660 and may include a conductive material such as tungsten. A second contact plug 670 may be formed in the second contact opening CTH2. The second contact plug 670 may be connected to the fifth material layer 540C and may include a conductive material such as tungsten. The channel contact plug CHCT may be formed in the channel contact opening CHCTH. The channel contact plug CHCT may include a conductive material such as tungsten. When forming the third contact plug 680, the second contact plug 670 or the channel contact plug CHCT may also be formed. Therefore, a process time and a process cost may be reduced by forming in a single operation the second contact plug 670, the third contact plug 680, or the channel contact plug CHCT.

According to the manufacturing method as described above, the first contact region CTR1 of the first gate structure 620G and the second contact region CTR2 of the second gate structure 640G may not overlap with each other. Therefore, the first contact plugs 660 and the third contact plugs 680 may be positioned in the first contact region CTR1, and the second contact plugs 670 may be positioned in the second contact region CTR2 spaced apart from the first contact region CTR1 in the first direction I.

When forming the channel opening CHH, the first contact opening CTH1 may also be formed. In addition, when forming the second channel sacrificial layer CHS2, the first contact plug 660 may be formed. When forming the second contact opening CTH2, the third contact opening CTH3 may also be formed. In addition, when forming the second contact plug 670, the third contact plug 680 may also be formed. Therefore, a process time and a process cost may be reduced by unifying the above operations of the process.

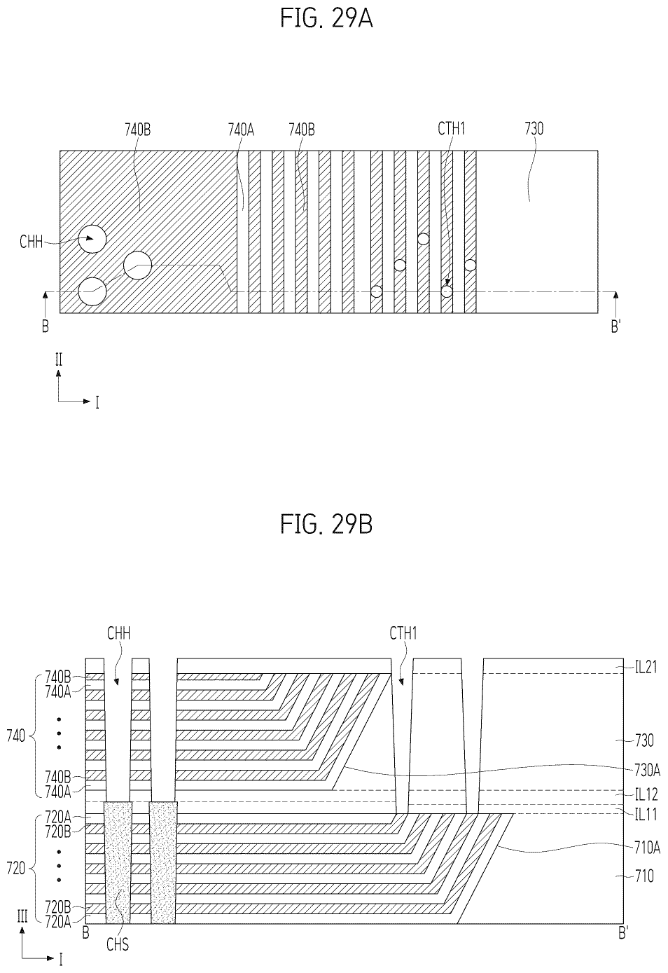

FIGS. 29A to 33B are diagrams illustrating a method of manufacturing a semiconductor device according to an embodiment of the present disclosure. FIGS. 29A, 30A, 31A, 32A, and 33A are plan views, and FIGS. 29B, 30B, 31B, 32B, and 33B may be B-B′ cross-sectional views of each A view. Hereinafter, any content repetitive to previously described content may be omitted.

Referring now to FIGS. 29A and 29B, a first support 710 including a first inclined surface 710A may be formed. The first inclined surface 710A may have an inclination of an acute angle. A first stack 720 may be formed by alternately stacking first material layers 720A and the second material layers 720B on the first support 710. The channel sacrificial layer CHS may be formed in the first stack 720.

Subsequently, a second support 730 including a second inclined surface 730A may be formed on the first support 710. The second inclined surface 730A may have an inclination of an acute angle. The second stack 740 may be formed by alternately stacking third material layers 740A and fourth material layers 740B on the second support 730.

The channel opening CHH exposing the channel sacrificial layer CHS may be formed in the second stack 740. The first contact opening CTH1 exposing at least one second material layer 720B among the second material layers 720B may be formed in the second support 730. When forming the channel opening CHH, the first contact opening CTH1 may also be formed.

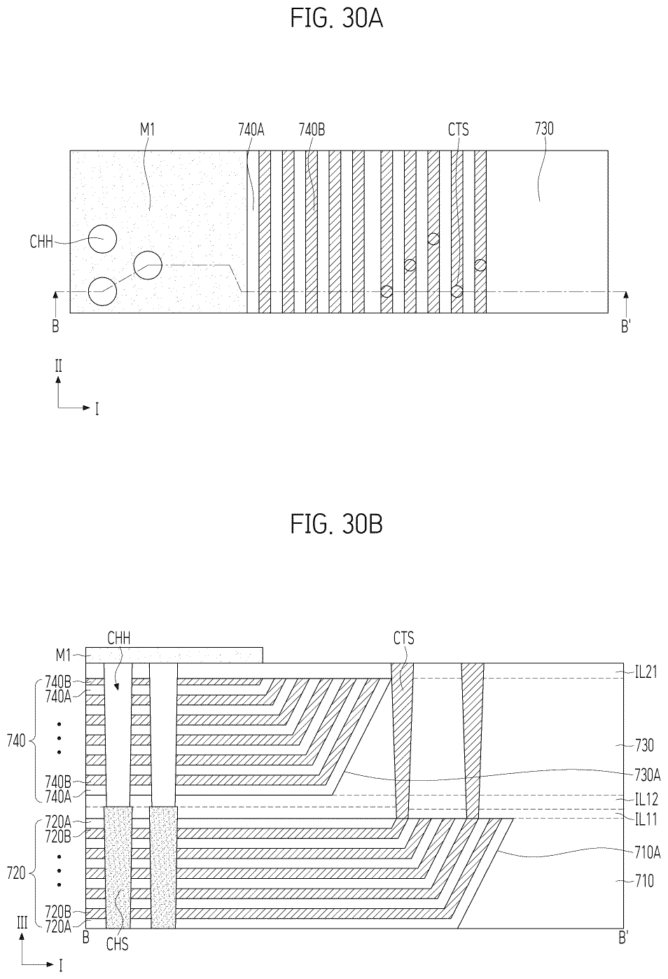

Referring now to FIGS. 30A and 30B, the first mask pattern M1 may be formed on the second stack 740. The first mask pattern M1 may cover the channel opening CHH and expose the first contact opening CTH1. Subsequently, the contact sacrificial layer CTS may be formed in the first contact opening CTH1. The contact sacrificial layer CTS may be formed to fill the first contact opening CTH1. The contact sacrificial layer CTS may include substantially the same material as the second material layers 720B.

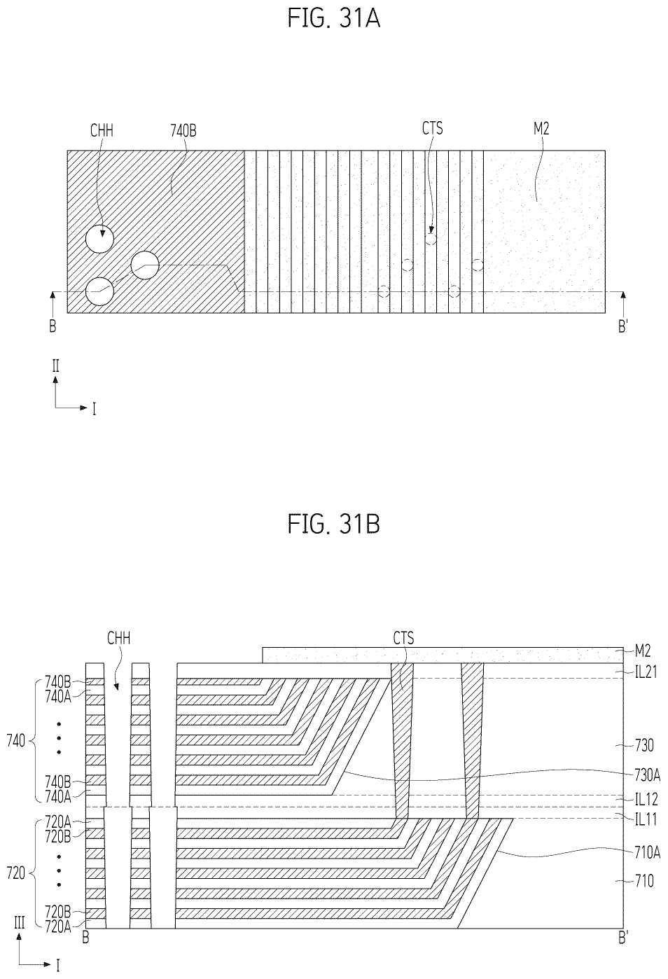

Referring now to FIGS. 31A and 31B, the second mask pattern M2 may be formed on the second stack 740. Before forming the second mask pattern M2, the first mask pattern M1 may be removed. The second mask pattern M2 may cover the contact sacrificial layer CTS and expose the channel opening CHH. Subsequently, the channel sacrificial layer CHS may be removed through the channel opening CHH to extend the channel opening CHH.

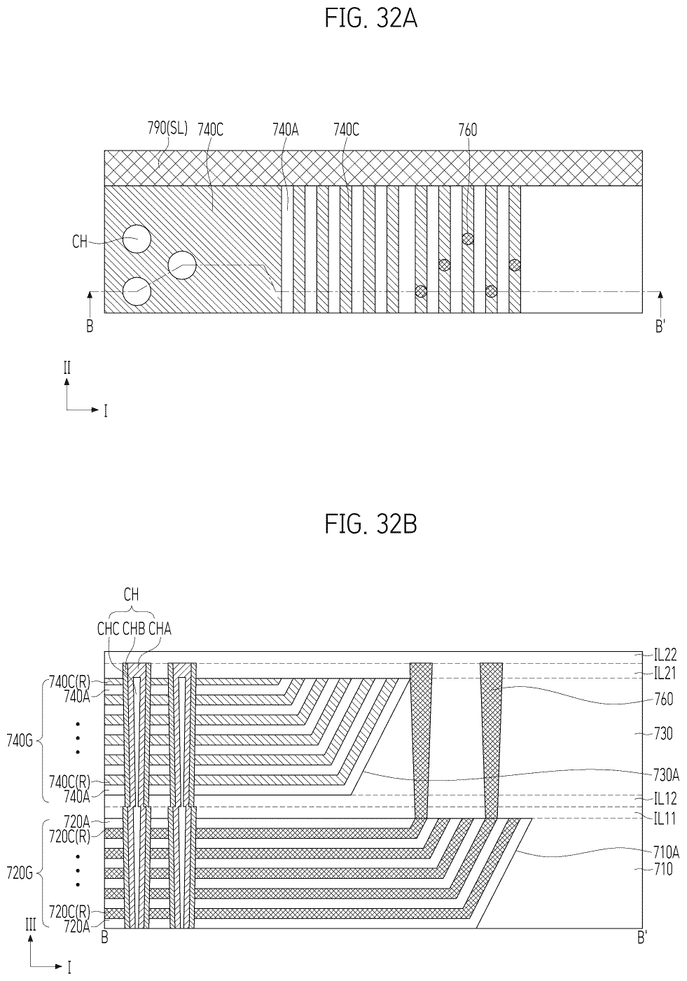

Referring now to FIGS. 32A and 32B, the channel structure CH may be formed in the channel opening CHH. The channel structure CH may include the channel layer CHA. The channel structure CH may include the memory layer CHB surrounding the channel layer CHA and the insulating core CHC in the channel layer CHA. Subsequently, the second mask pattern M2 may be removed.

Subsequently, the slit SL extending through the second stack 740 and the first stack 720 may be formed. Subsequently, the recesses R may be formed by removing the second material layers 720B and the fourth material layers 740B through the slit SL. The first contact opening CTH1 may be reopened by removing the contact sacrificial layer CTS through the slit SL. Because the second material layers 720B, the fourth material layers 740B, and the contact sacrificial layer CTS include substantially the same material, the second material layers 720B, the fourth material layers 740B, and the contact sacrificial layer CTS may be simultaneously removed. That is, the second material layers 720B, the fourth material layers 740B, and the contact sacrificial layer CTS may be removed through the slit SL.

Subsequently, a first contact plug 760 may be formed by forming a fifth material layer 720C in the first contact opening CTH1. For example, the fifth material layer 720C may be formed in the first contact opening CTH1 through the slit SL. For example, the fifth material layer 720C may include a conductive material such as tungsten.

Fifth material layers 720C and 740C may be formed in the recesses R. For example, the fifth material layers 720C may be formed in the recesses R through the slits SL. Therefore, a first gate structure 720G including the first material layers 720A and the fifth material layers 720C alternately stacked may be formed. A second gate structure 740G including the first material layers 740A and the fifth material layers 740C alternately stacked may be formed.

The recess R and the first contact opening CTH1 connected to the recess R may be simultaneously filled with the fifth material layers 720C and 740C. For example, among the fifth material layers 720C and 740C, the fifth material layers 720C and 740C formed in the gate structures 720G and 740G may be used as the gate line and the fifth material layer 720C formed in the first contact opening CTH1 may be used as the first contact plug 760. Therefore, a process time and a process cost may be reduced by forming the first contact plug 760 by utilizing a process of replacing the second material layers 720B and the fourth material layers 740B with the fifth material layers 720C and 740C.

A slit structure 790 may be formed in the slit SL. The slit structure 790 may be an insulating layer including an insulating material such as an oxide. Alternatively, the slit structure 490 may include a source contact structure connected to the source structure.

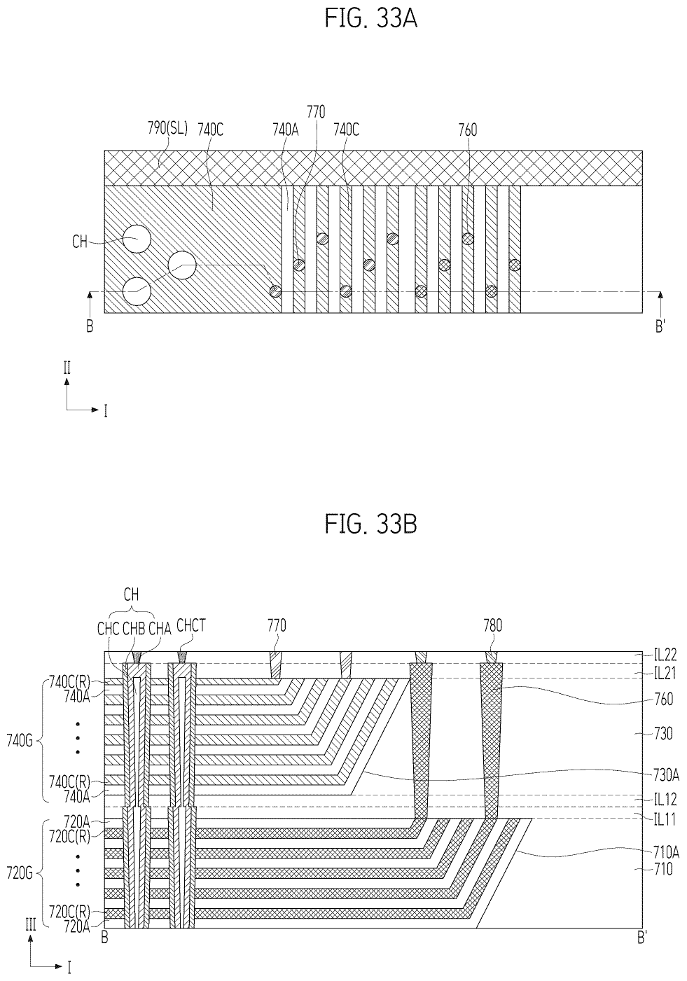

Referring now to FIGS. 33A and 33B, a third contact plug 780 connected to the first contact plug 760 may be formed. A second contact plug 770 connected to at least one fifth material layer 740C among the fifth material layers 740C of the second gate structure 740G may be formed. The channel contact plug CHCT connected to the channel structure CH may be formed. When forming the third contact plug 780, the second contact plug 770 or the channel contact plug CHCT may also be formed.

According to the manufacturing method as described above, when forming the gate structures 720G and 740G by forming the fifth material layers 720C and 740C in the recesses R, the first contact plug 760 may be formed by forming the fifth material layer 720C in the first contact opening CTH1. Therefore, a process time and a process cost may be reduced by unifying the above operations of the process.

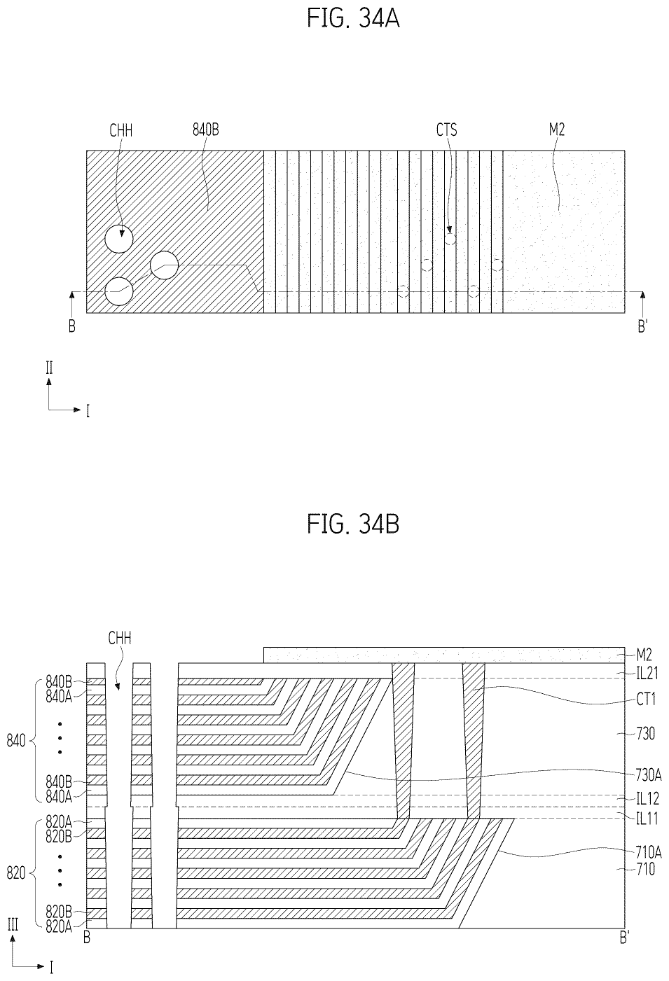

FIGS. 34A to 36B are diagrams illustrating a method of manufacturing a semiconductor device according to an embodiment of the present disclosure. FIGS. 34A, 35A, and 36A are plan views, and FIGS. 34B, 35B, and 36B may be B-B′ cross-sectional views of each A view. Hereinafter, any content repetitive to previously described content may be omitted.

Referring now to FIGS. 34A and 34B, a first support 810 including a first inclined surface 810A may be formed. The first inclined surface 810A may have an inclination of an acute angle. A first stack 820 may be formed by alternately stacking first material layers 820A and second material layers 820B on the first support 810. The channel sacrificial layer (not shown) may be formed in the first stack 820. Subsequently, a second support 830 including a second inclined surface 830A may be formed on the first support 810. The second inclined surface 830A may have an inclination of an acute angle. A second stack 840 may be formed by alternately stacking third material layers 840A and fourth material layers 840B on the second support 830.

Thereafter, the channel opening CHH exposing the channel sacrificial layer CHS may be formed in the second stack 840. The first contact opening (not shown) exposing at least one second material layer 820B among the second material layers 820B may be formed in the second support 830. When forming the channel opening CHH, the first contact opening may be formed.

Subsequently, the first mask pattern (not shown) may be formed on the second stack 840. The first mask pattern M1 may cover the channel opening CHH and expose the first contact opening. Subsequently, the contact sacrificial layer CTS may be formed in the first contact opening. The contact sacrificial layer CTS may include substantially the same material as the second material layers 820B.

Subsequently, the second mask pattern M2 may be formed on the second stack 840. Before forming the second mask pattern M2, the first mask pattern may be removed. The second mask pattern M2 may cover the contact sacrificial layer CTS and expose the channel opening CHH. Subsequently, the channel sacrificial layer CHS may be removed through the channel opening CHH to extend the channel opening CHH.

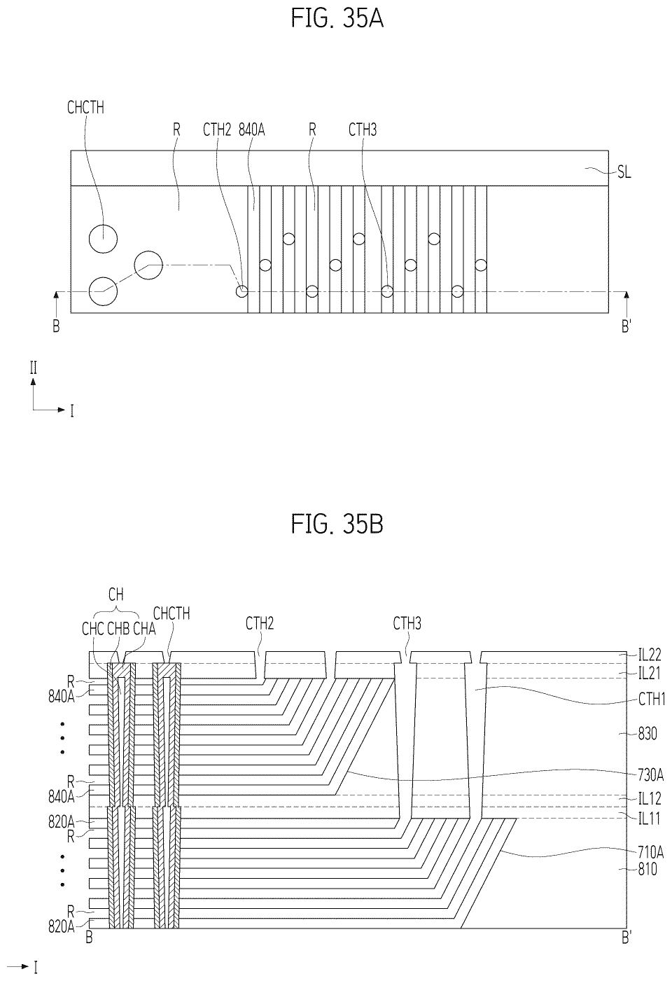

Referring now to FIGS. 35A and 35B, the channel structure CH may be formed in the channel opening CHH. Subsequently, the second mask pattern M2 may be removed. Subsequently, the slit SL extending through the second stack 840 and the first stack 820 may be formed.

The third contact opening CTH3 exposing the contact sacrificial layer CTS may be formed. The second contact opening CTH2 exposing at least one fourth material layer 840B among the fourth material layers 840B may be formed. The channel contact opening CHCTH exposing the channel structure CH may be formed. When forming the third contact opening CTH3, the second contact opening CTH2 or the channel contact opening CTH3 may also be formed.

Thereafter, the recesses R may be formed by removing the second material layers 820B and the fourth material layers 840B through the slit SL. The first contact opening CTH1 may be reopened by removing the contact sacrificial layer CTS through the slit SL. For example, the contact sacrificial layer CTS or at least one second material layer 820B among the second material layers 820B may be removed through the third contact opening CTH3. At least one fourth material layer 840B among the fourth material layers 840B may be removed through the second contact opening CTH2. The second material layers 820B and the contact sacrificial layer CTS may be removed through the slit SL and the third contact opening CTH3. The fourth material layers 840B may be removed through the slit SL and the second contact opening CTH2. Therefore, because the second material layer 820B and the contact sacrificial layer CTS may be removed from one end to another end through the slit SL and the second material layer 820B and the contact sacrificial layer CTS may be removed from another end to one end through the third contact opening CTH3, a process time and a process cost may be reduced by removing the second material layer 820B and the contact sacrificial layer CTS at a speed higher than that of a case where the second material layer 820B and the contact sacrificial layer CTS are removed in one direction.

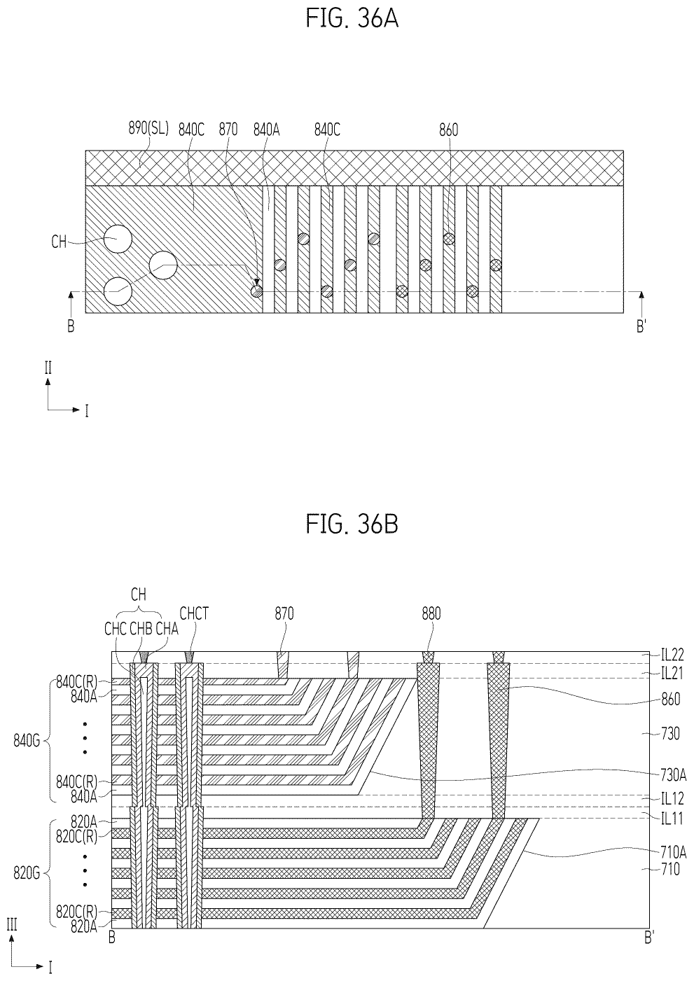

Referring now to FIGS. 36A and 36B, a first contact plug 860 may be formed by forming a fifth material layer 820C in the first contact opening CTH1. A third contact plug 880 may be formed by forming the fifth material layer 820C in the third contact opening CTH3. For example, the first contact plug 860 and the third contact plug 880 may be formed by forming the fifth material layer 820C in the first contact opening CTH1 and the third contact opening CTH3 through the slit SL. Fifth material layers 820C and 840C may be formed in the recesses R. For example, the fifth material layers 820C may be formed in the recesses R through the slit SL, the second contact opening CTH2, and the third contact opening CTH3. Therefore, a first gate structure 820G including the first material layers 820A and the fifth material layers 820C alternately stacked may be formed. A second gate structure 840G including the first material layers 840A and the fifth material layers 840C alternately stacked may be formed.

A second contact plug 870 may be formed in the second contact opening CTH2. The channel contact plug CHCT may be formed in the channel contact opening CHCTH. When forming the first contact plug 860 or the third contact plug 880, the second contact plug 870 or the channel contact plug CHCT may also be formed.

The recess R, the first contact opening CTH1 connected to the recess R, the third contact opening CTH3 connected to the first contact opening CTH1, and the second contact opening CTH2 connected to the recess R may be simultaneously filled with the fifth material layers 820C and 840C. For example, among the fifth material layers 820C and 840C, the fifth material layers 820C and 840C formed in the gate structures 820G and 840G may be used as the gate line, the fifth material layer 820C formed in the first contact opening CTH1 may be used as the first contact plug 860, the fifth material layer 820C formed in the third contact opening CTH3 may be used as the third contact plug 880, and the fifth material layer 840C formed in the second contact opening CTH2 may be used as the second contact plug 870.

A slit structure 890 may be formed in the slit SL. The slit structure 890 may be an insulating layer including an insulating material such as an oxide. Alternatively, the slit structure 890 may include a source contact structure connected to the source structure.

According to the manufacturing method as described above, the second material layer 820B and the contact sacrificial layer CTS may be removed through the slit SL and the third contact opening CTH3. In addition, the first contact plug 860 may be formed through the slit SL and the third contact opening CTH3. Therefore, because a process may be performed at a speed higher than that of a case where the process is performed through the slit SL or the third contact opening CTH3, a process time and a process cost may be reduced.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a first support including a first inclined surface;
a first gate structure including first insulating layers and first conductive layers alternately stacked along the first inclined surface;
a second support positioned over or on the first support and including a second inclined surface;
a second gate structure including second insulating layers and second conductive layers alternately stacked along the second inclined surface;
a first contact plug extending through the second gate structure and connected to at least one first conductive layer among the first conductive layers; and
a second contact plug disposed over or on the second gate structure and connected to at least one second conductive layer among the second conductive layers.

2. The semiconductor device of claim 1, further comprising:
an insulating spacer surrounding a sidewall of the first contact plug.

3. The semiconductor device of claim 1, wherein the first conductive layers extend in a first direction, and the first contact plug and the second contact plug are adjacent to each other in a second direction crossing the first direction.

4. The semiconductor device of claim 1, wherein the first gate structure includes a first cell region in which the first conductive layers extend in a first direction and a first contact region extending along the first inclined surface,
wherein the second gate structure includes a second cell region in which the second conductive layers extend in the first direction and a second contact region extending along the second inclined surface, and
wherein the first contact region and the second contact region overlap in a third direction crossing the first direction.

5. The semiconductor device of claim 4, wherein in the first contact region, a top surface of the first conductive layers is positioned at substantially the same level.

6. The semiconductor device of claim 4, wherein in the second contact region, a top surface of the second conductive layers is positioned at substantially the same level.

7. The semiconductor device of claim 1, further comprising:
a channel structure extending through the second gate structure and the first gate structure; and
a slit structure extending through the second gate structure and the first gate structure.

8. The semiconductor device of claim 7, wherein a top surface of the channel structure is positioned at substantially the same level as a top surface of the first contact plug.

9. The semiconductor device of claim 1, wherein the first inclined surface and the second inclined surface have an inclination of an acute angle.

10. The semiconductor device of claim 1, wherein at least one first conductive layer among the first conductive layers and the first contact plug are connected and forms a single layer.

11. The semiconductor device of claim 1, further comprising:
a third contact plug positioned over or on the first contact plug and connected to the first contact plug.

12. The semiconductor device of claim 11, wherein at least one first conductive layer among the first conductive layers, the first contact plug, and the third contact plug are connected and forms a single layer.

13. A semiconductor device comprising:
a first support including a first inclined surface;
a first gate structure including first insulating layers and first conductive layers alternately stacked along the first inclined surface;
a second support positioned over or on the first support and including a second inclined surface;
a second gate structure including second insulating layers and second conductive layers alternately stacked along the second inclined surface;
a channel structure extending through the second gate structure and the first gate structure;
a first contact plug including a top surface positioned at substantially the same level as a top surface of the channel structure, on the first gate structure; and
a second contact plug connected to at least one second conductive layer among the second conductive layers, on the second gate structure.

14. The semiconductor device of claim 13, wherein the first contact plug extends through the second gate structure and is connected to at least one first conductive layer among the first conductive layers.

15. The semiconductor device of claim 14, wherein the first contact plug is connected to at least one first conductive layer among the first conductive layers and forms a single layer.

16. The semiconductor device of claim 14, further comprising:
a third contact plug positioned over or on the first contact plug and connected to the first contact plug.

17. The semiconductor device of claim 16, wherein the third contact plug is connected to the first contact plug and at least one first conductive layer among the first conductive layers and forms a single layer.

18. The semiconductor device of claim 13, wherein the first contact plug extends through the second support and is connected to at least one first conductive layer among the first conductive layers.

19. The semiconductor device of claim 18, wherein the first contact plug is connected to at least one first conductive layer among the first conductive layers and forms a single layer.

20. The semiconductor device of claim 18, further comprising:
a third contact plug positioned over or on the first contact plug and connected to the first contact plug.

21. The semiconductor device of claim 20, wherein the third contact plug is connected to the first contact plug and at least one first conductive layer among the first conductive layers and forms a single layer.

22. The semiconductor device of claim 13, wherein the first gate structure includes a first cell region in which the first conductive layers extend in a first direction and a first contact region extending along the first inclined surface,
wherein the second gate structure includes a second cell region in which the second conductive layers extend in the first direction and a second contact region extending along the second inclined surface,
wherein the first contact region and the second contact region overlap in a third direction crossing the first direction.

23. The semiconductor device of claim 22, wherein a top surface of the first conductive layers is positioned at substantially the same level, in the first contact region.

24. The semiconductor device of claim 22, wherein a top surface of the second conductive layers is positioned at substantially the same level, in the second contact region.

25. The semiconductor device of claim 13, wherein the first inclined surface and the second inclined surface have an inclination of an acute angle.
